(19) United States
(12) Patent Application Publication
(10) Pub. No.: US 2024/0282690 A1
(43) Pub. Date: Aug. 22, 2024

(54) SEMICONDUCTOR DEVICE

(71) Applicant: Rohm Co., Ltd., Kyoto-shi (JP)

(72) Inventors: Kota ISE, Kyoto-shi (JP); Koshun SAITO, Kyoto-shi (JP)

(21) Appl. No.: 18/652,315

(22) Filed: May 1, 2024

Related U.S. Application Data
(63) Continuation of application No. PCT/JP2022/043496, filed on Nov. 25, 2022.

(30) Foreign Application Priority Data
Dec. 3, 2021 (JP) 2021-196624

(51) Int. Cl. H01L 23/498; H01L 23/00; H01L 23/31

(52) U.S. Cl. CPC H01L 23/49838; H01L 23/3121; H01L 24/32; H01L 2224/32225; H01L 2224/32245; H01L 2924/1815

(57) ABSTRACT

A semiconductor device includes a lead with a terminal, and a sealing resin partially covering the terminal. The lead includes a base and metal layer covering the base. The base has a first terminal-extending portion forming the terminal. The first terminal-extending portion, exposed from the sealing resin, extends in a first direction crossing the thickness direction. The first terminal-extending portion includes a first end facing in the first direction and a first side wall facing in a second direction crossing the thickness and first directions. The first side wall has, in the first direction, a first side closer to the first end, a second side closer to the sealing resin, and a third side between the first side and the second side. The metal layer, covering the first end, the first side and the second side, is provided at a location avoiding the third side.

### TECHNICAL FIELD

The present disclosure relates to a semiconductor device.

### BACKGROUND ART

Various configurations have been proposed for semiconductor devices with semiconductor elements. An example of a conventional semiconductor device is disclosed in JP-A-2017-135241. The semiconductor device disclosed in JP-A-2017-135241 includes a semiconductor element, a lead, and a sealing resin. The semiconductor element is supported on the lead. The sealing resin covers a part of the lead, and the semiconductor element. The lead has a plurality of terminal portions. Each terminal portion includes a portion exposed from the sealing resin, and is bonded with a bonding material, such as solder, when mounted on a circuit board, for example. The lead is covered with a plating layer at appropriate portions. The extremity of each terminal portion is not covered with a plating layer, and a cut surface, which is formed by cutting e.g. a metal plate (lead frame) used for manufacturing the semiconductor device, is exposed at such extremity. The cut surface at the extremity of each terminal portion has poor wettability to solder as compared with a plating layer. This may decrease the reliability of mounting of the semiconductor device on a circuit board. Also, during the cutting, metal burrs are generated at the extremity of the terminal portions, and if these metal burrs protrude from the extremity of the terminal portions, the reliability of mounting of the semiconductor device may be decreased.

### BRIEF DESCRIPTION OF THE DRAWINGS

FIG. 1 is a plan view of a semiconductor device according to a first embodiment of the present disclosure.

FIG. 2 is a bottom view of the semiconductor device shown in FIG. 1.

FIG. 3 is a plan view (seen through a sealing resin) of the semiconductor device shown in FIG. 1.

FIG. 4 is a right side view of the semiconductor device shown in FIG. 1.

FIG. 5 is a left side view of the semiconductor device shown in FIG. 1.

FIG. 6 is a sectional view taken along line VI-VI in FIG. 3.

FIG. 7 is a sectional view taken along line VII-VII in FIG. 3.

FIG. 8 is a sectional view taken along line VIII-VIII in FIG. 3.

FIG. 9 is an enlarged view of an area around a first terminal portion in FIG. 1.

FIG. 10 is an enlarged view of an area around a second terminal portion in FIG. 1.

FIG. 11 is a right side view of FIG. 9.

FIG. 12 is a left side view of FIG. 9.

FIG. 13 is a right side view of FIG. 10.

FIG. 14 is a left side view of FIG. 10.

FIG. 15 is a sectional view taken along line XV-XV in FIG. 9.

FIG. 16 is a sectional view taken along line XVI-XVI in FIG. 9.

FIG. 17 is a sectional view taken along line XVII-XVII in FIG. 10.

FIG. 18 is a plan view showing a part of the lead frame used in manufacturing the semiconductor device shown in FIG. 1.

FIG. 19 is a plan view of a semiconductor device according to a first variation of the first embodiment.

FIG. 20 is an enlarged view of an area around the first terminal portion in FIG. 19.

FIG. 21 is an enlarged view of an area around the second terminal portion in FIG. 19.

FIG. 22 is a plan view showing a part of the lead frame used in manufacturing the semiconductor device shown in FIG. 19.

FIG. 23 is a plan view of a semiconductor device according to a second variation of the first embodiment.

FIG. 24 is an enlarged view of an area around the first terminal portion in FIG. 23.

FIG. 25 is an enlarged view of an area around the second terminal portion in FIG. 23.

FIG. 26 is a plan view showing a part of the lead frame used in manufacturing the semiconductor device shown in FIG. 23.

FIG. 27 is a plan view of a semiconductor device according to a second embodiment of the present disclosure.

FIG. 28 is a bottom view of the semiconductor device shown in FIG. 27.

FIG. 29 is a plan view (seen through the sealing resin) of the semiconductor device shown in FIG. 27.

FIG. 30 is a right side view of the semiconductor device shown in FIG. 27.

FIG. 31 is a left side view of the semiconductor device shown in FIG. 27.

FIG. 32 is a sectional view taken along line XXXII-XXXII in FIG. 29.

FIG. 33 is a sectional view taken along line XXXIII-XXXIII in FIG. 29.

FIG. 34 is a sectional view taken along line XXXIV-XXXIV in FIG. 29.

FIG. 35 is an enlarged view of an area around the second terminal portion in FIG. 27.

FIG. 36 is a plan view of a semiconductor device according to a variation of the second embodiment.

FIG. 37 is a sectional view taken along line XXXVII-XXXVII in FIG. 36.

FIG. 38 is a sectional view taken along line XXXVIII-XXXVIII in FIG. 36.

FIG. 39 is an enlarged view of an area around the second terminal portion in FIG. 36.

FIG. 40 is a plan view showing a part of the lead frame used in manufacturing the semiconductor device shown in FIG. 36.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment

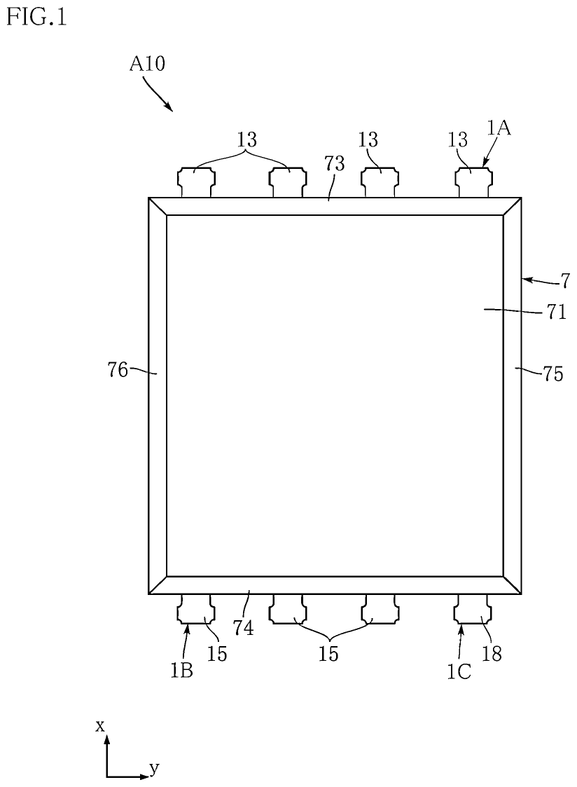

A semiconductor device A10 according to a first embodiment of the present disclosure will be described based on FIGS. 1 to 10. The semiconductor device A10 includes a plurality of leads 1A, 1B and 1C, a semiconductor element 2, an insulating part 3, a metal laminate part 4, a conductive member 5, conductive bonding materials 61, 62 and 63, and a sealing resin 7.

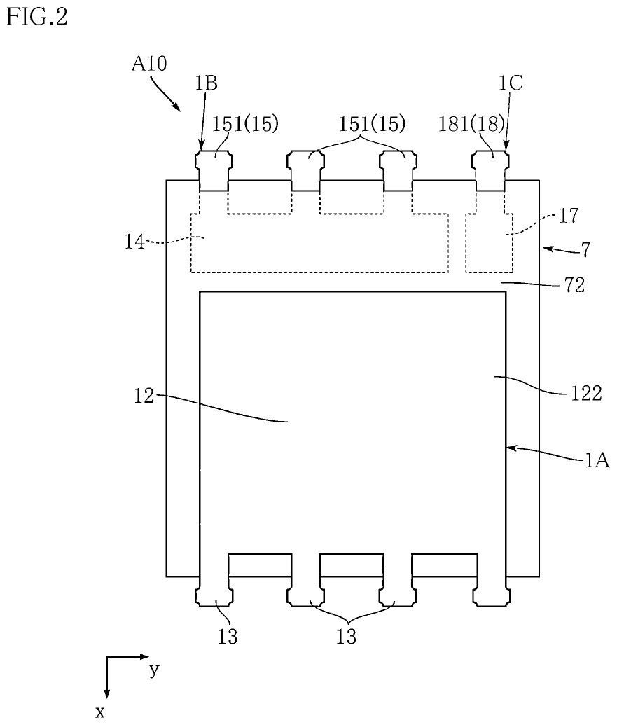

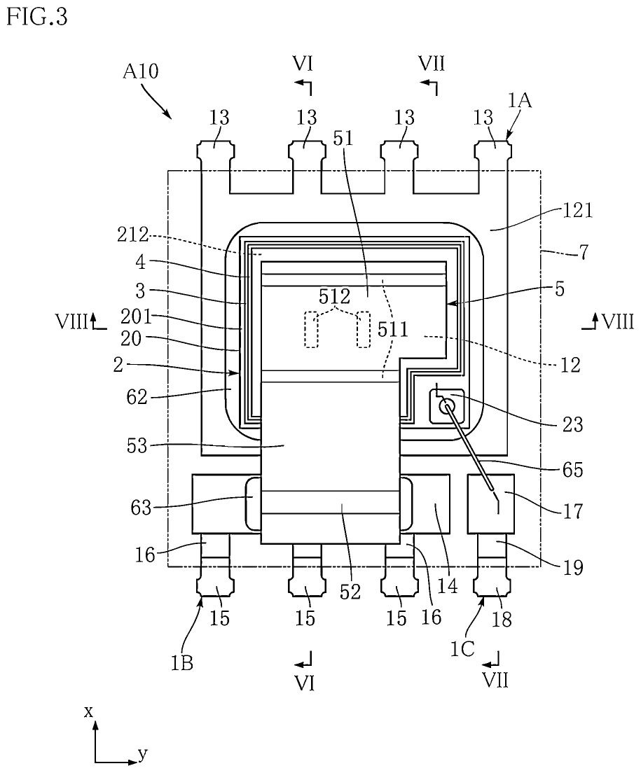

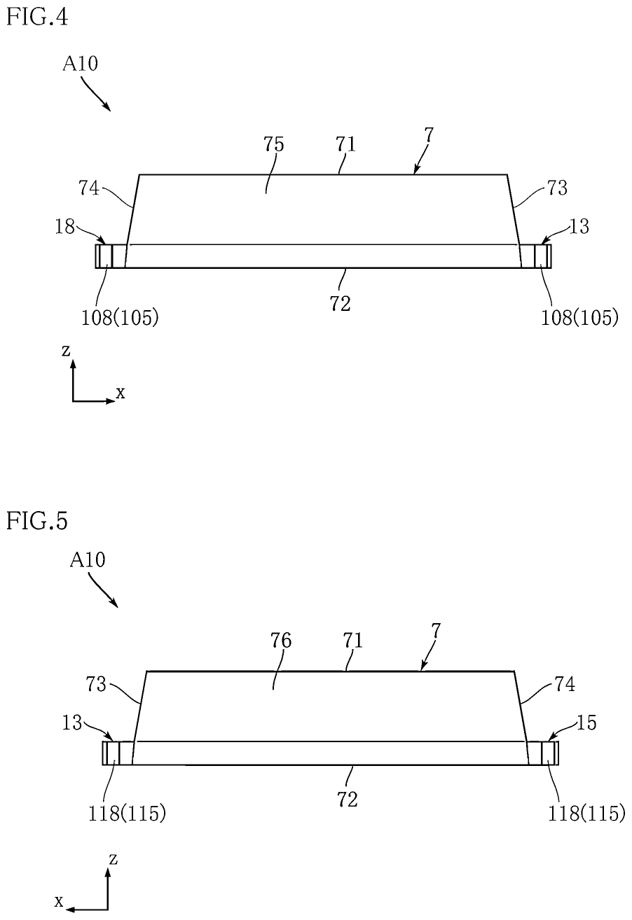

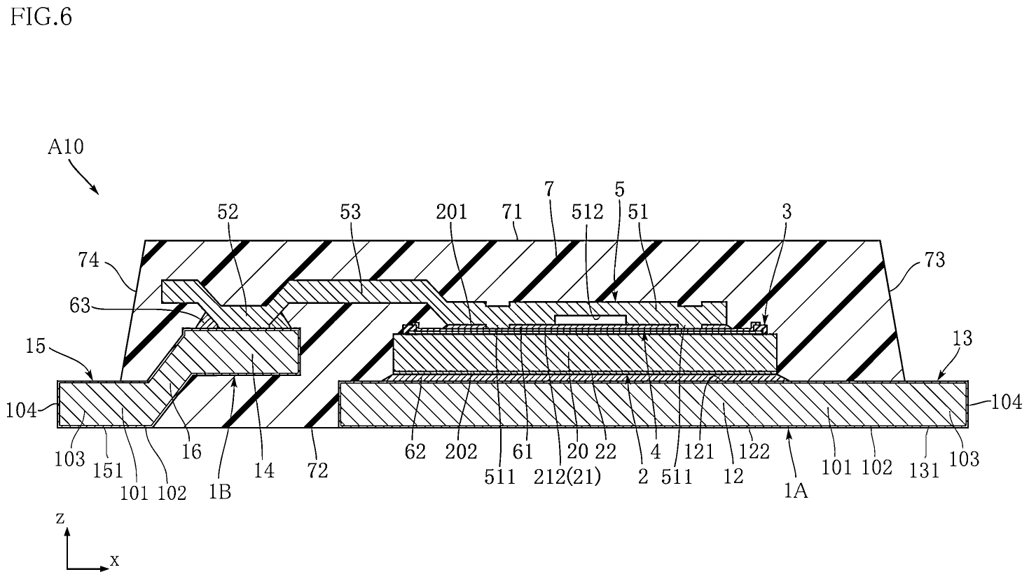

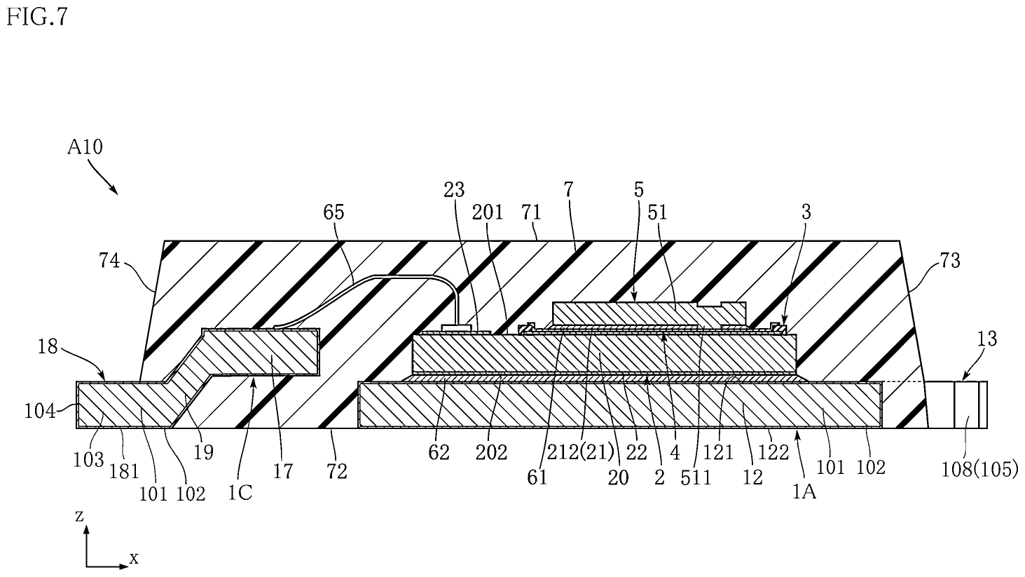

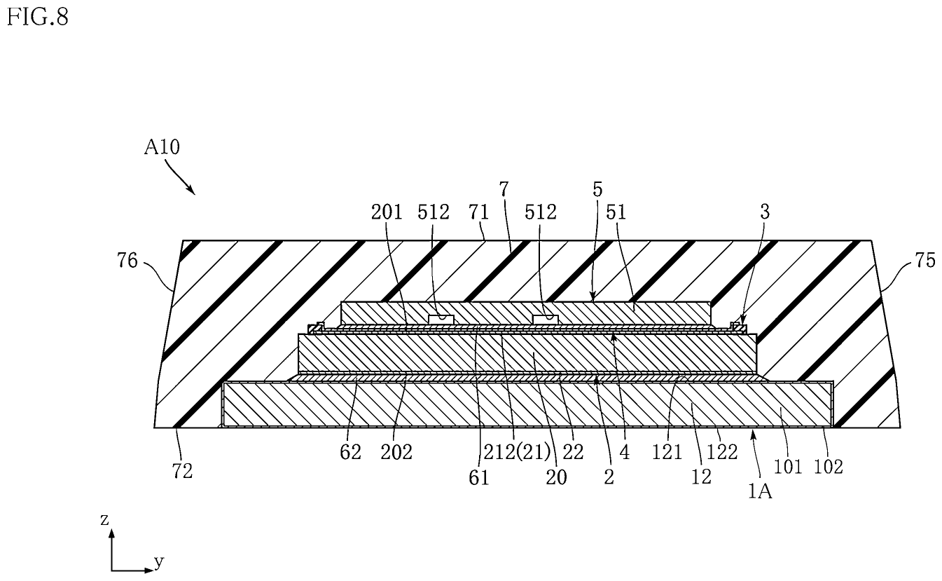

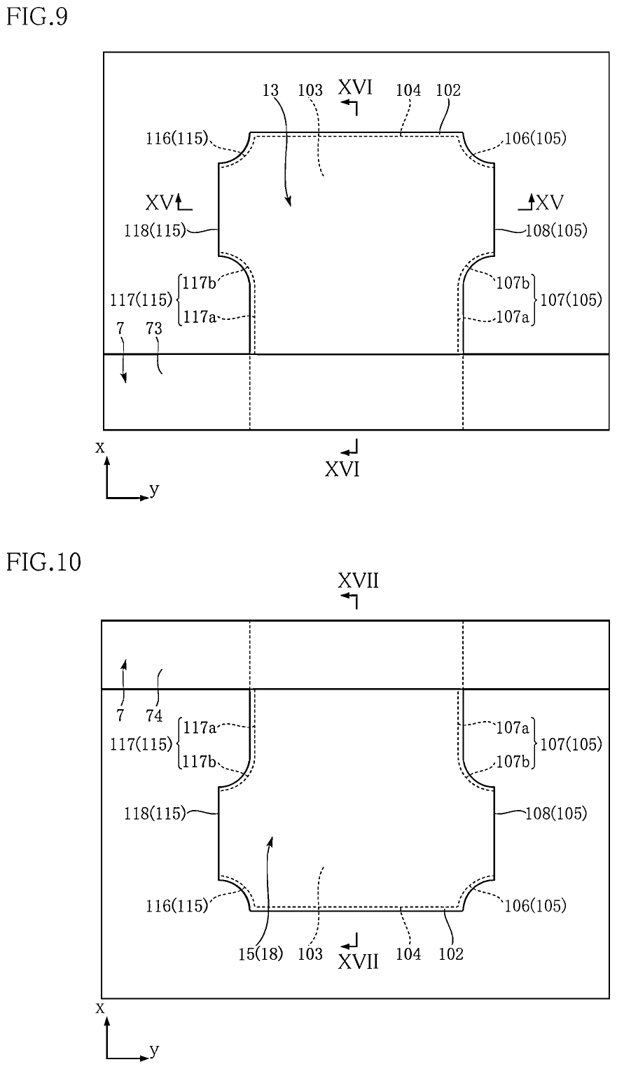

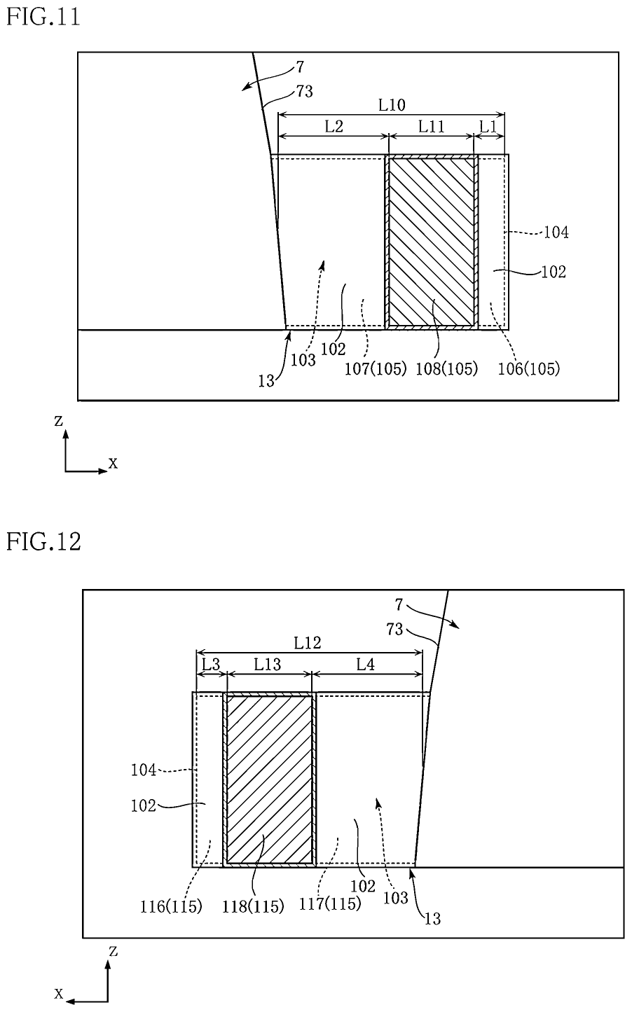

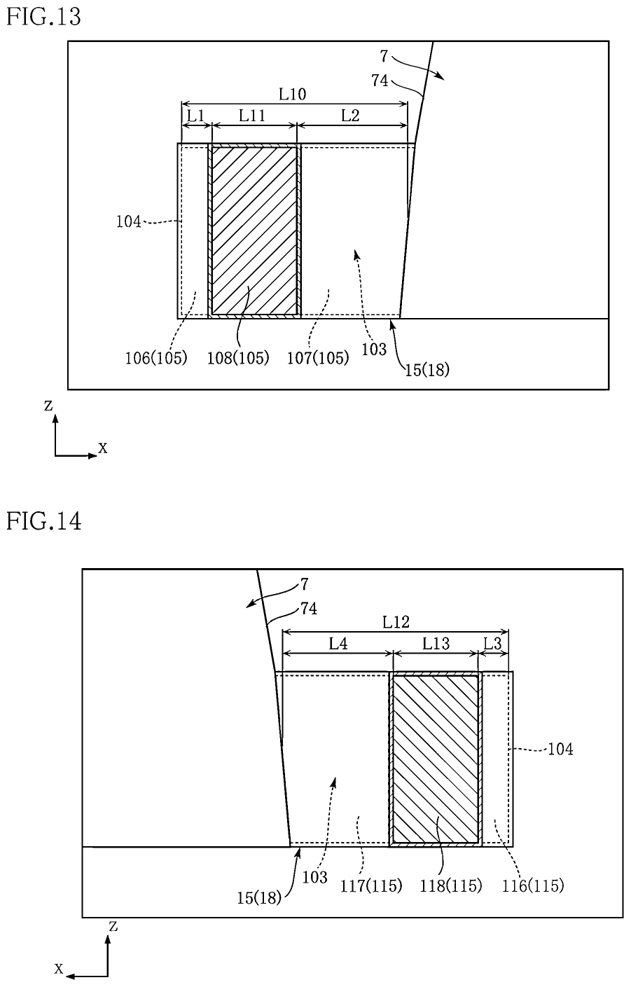

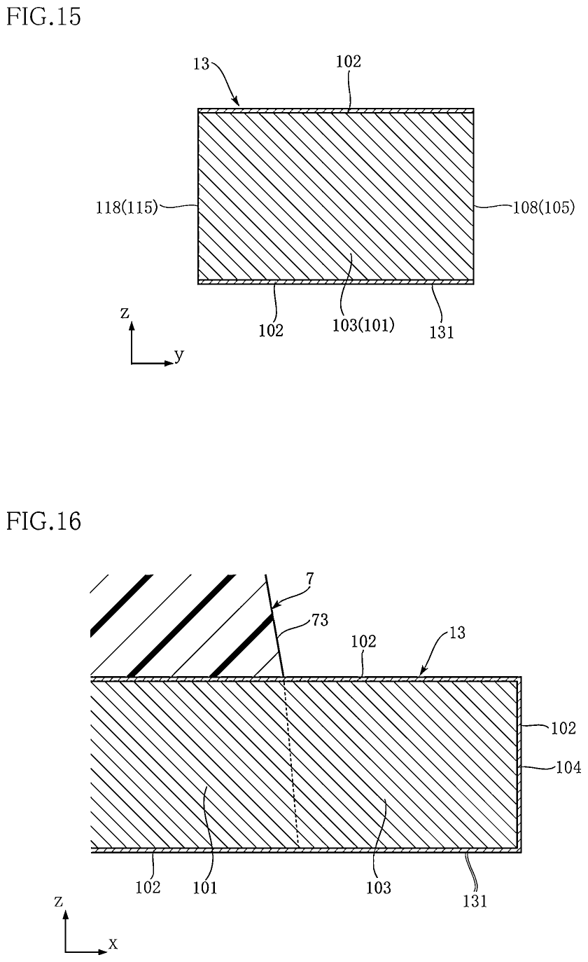

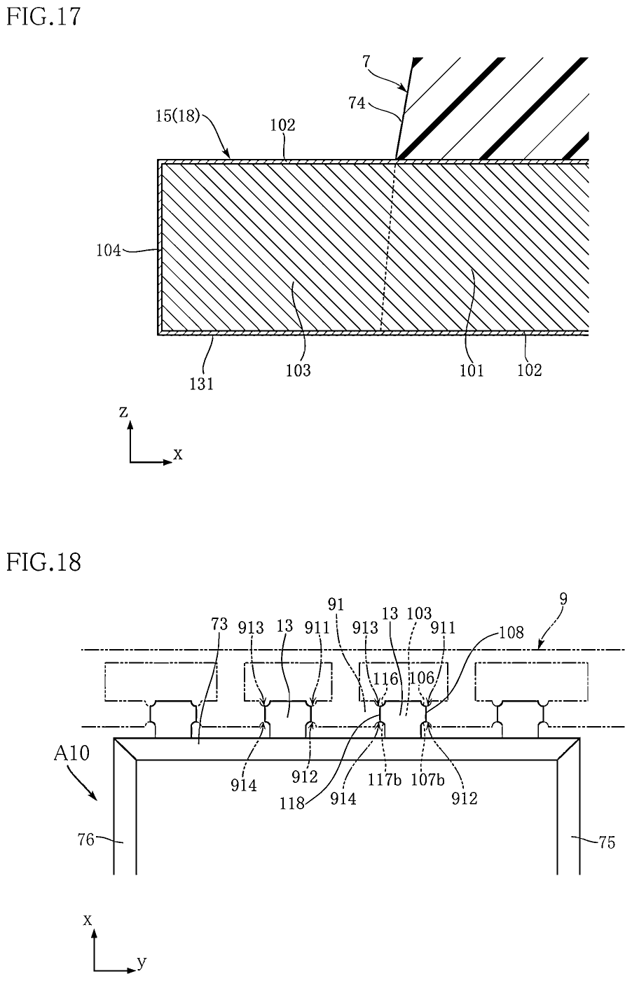

FIG. 1 is a plan view of the semiconductor device A10. FIG. 2 is a bottom view of the semiconductor device A10. FIG. 3 is a plan view of the semiconductor device A10. FIG. 4 is a right side view of the semiconductor device A10. FIG. 5 is a left side view of the semiconductor device A10. FIG. 6 is a sectional view taken along line VI-VI in FIG. 3. FIG. 7 is a sectional view taken along line VII-VII in FIG. 3. FIG. 8 is a sectional view taken along line VIII-VIII in FIG. 3. FIG. 9 is a partial enlarged view of FIG. 1 (enlarged view of the area around a first terminal portion 13, described later). FIG. 10 is a partial enlarged view of FIG. 1 (enlarged view of the area around a second terminal portion 15 or 18, described later). FIG. 11 is a right side view of FIG. 9. FIG. 12 is a left side view of FIG. 9. FIG. 13 is a right side view of FIG. 10. FIG. 14 is a left side view of FIG. 10. FIG. 15 is a sectional view taken along line XV-XV in FIG. 9. FIG. 16 is a sectional view taken along line XVI-XVI in FIG. 9. FIG. 17 is a sectional view taken along line XVII-XVII in FIG. 10. In FIG. 3, the sealing resin 7 is transparent for the convenience of understanding.

In the description of the semiconductor device A10, the thickness direction of the semiconductor element 2 is referred to as the “thickness direction z”. A direction orthogonal to the thickness direction z is referred to as the “first direction x” . The direction orthogonal to the thickness direction z and the first direction x is referred to as the “second direction y”. As shown in FIGS. 1 and 2, the semiconductor device A10 is rectangular (or generally rectangular) as viewed in the thickness direction z. The size of the semiconductor device A10 is not particularly limited.

The lead 1A, the lead 1B and the lead 1C are formed by subjecting a metal plate (lead frame) to working such as punching or bending. The thickness of the lead 1A, the lead 1B and the lead 1C is not particularly limited and may be 0.1 mm to 0.3 mm, for example. As will be described later, each of the leads 1A to 1C includes a base material 101 and a metal layer 102 (see FIGS. 6 to 8). The constituent material of the base material 101 is not particularly limited, and the base material 101 is made of, for example, copper (Cu) or nickel (Ni), or an alloy of these. The metal layer 102 covers a part of the base material 101, and covers most of the base material 101 in the present embodiment. The metal layer 102 is, for example, a plating layer formed on the surface of the base material 101. The constituent material of the plating layer is not particularly limited, and the plating layer is made of, for example, an alloy containing Sn as the main component.

As shown in FIG. 3, the lead 1A is spaced apart from the lead 1B and the lead 1C in the first direction x. The lead 1B and the lead 1C are arranged side by side in the second direction y. The leads 1A to 1C are spaced apart from each other as viewed in the thickness direction z. The lead 1A is the largest while the lead 1C is the smallest in size as viewed in the thickness direction z.

As shown in FIGS. 3 and 6 to 8, the lead 1A has a die pad 12 and a plurality of (four in the present embodiment) first terminal portions 13. The die pad 12 is, for example, rectangular as viewed in the thickness direction z. The die pad 12 includes a first surface 121 and a reverse-surface mount portion 122. The first surface 121 faces a first side in the thickness direction z, and the reverse-surface mount portion 122 faces a side opposite to the side that the first surface 121 faces (a second side in the thickness direction z). The semiconductor element 2 is mounted on the first surface 121. As shown in FIGS. 2 and 6, the reverse-surface mount portion 122 is exposed from the sealing resin 7. When the semiconductor device A10 is mounted on a circuit board, not shown, the reverse-surface mount portion 122 is bonded with a bonding material, such as solder.

The first terminal portions 13 are located on a first side in the first direction x (the right side in FIG. 6) with respect to the die pad 12. Each of the first terminal portions 13 is connected to the die pad 12 on the first side in the first direction x and extends toward the first side in the first direction x. The first terminal portions 13 are arranged at intervals in the second direction y. Each first terminal portion 13 is an example of the “terminal portion” that extends in a direction orthogonal to the thickness direction z (the first direction x in the illustrated example). Each first terminal portion 13 has a reverse-surface mount portion 131. The reverse-surface mount portion 131 faces the second side in the thickness direction z (the lower side in FIG. 6). The reverse-surface mount portion 122 is exposed from the sealing resin 7. When the semiconductor device A10 is mounted on a circuit board, not shown, the reverse-surface mount portion 131 is bonded with a bonding material, such as solder.

As shown in FIGS. 3 and 6, the lead 1B includes a pad portion 14, a plurality of (three in the present embodiment) second terminal portions 15, and a plurality of (three in the present embodiment) bent portions 16. The pad portion 14 is located on the first side in the thickness direction z (the upper side in FIG. 6) with respect to the second terminal portions 15. Also, the pad portion 14 is located inward in the first direction x with respect to the second terminal portions 15.

The second terminal portions 15 are located on a second side in the first direction x (the left side in FIG. 6) with respect to the die pad 12 of the lead 1A. Each of the second terminal portions 15 extends toward the second side in the first direction x. The second terminal portions 15 are arranged at intervals in the second direction y. Each second terminal portion 15 is an example of the “terminal portion” that extends in a direction orthogonal to the thickness direction z (the first direction x in the illustrated example). Each second terminal portion 15 has a reverse-surface mount portion 151. The reverse-surface mount portion 151 faces the second side in the thickness direction z (the lower side in FIG. 6). The reverse-surface mount portion 151 is exposed from the sealing resin 7. When the semiconductor device A10 is mounted on a circuit board, not shown, the reverse-surface mount portion 151 is bonded with a bonding material, such as solder. The bent portions 16 individually connect the pad portion 14 and the second terminal portions 15 and have a bent shape as viewed in the second direction y.

As shown in FIGS. 3 and 7, the lead 1C has a pad portion 17, a second terminal portion 18, and a bent portion 19. The pad portion 17 is located on the first side in the thickness direction z (the upper side in FIG. 7) with respect to the second terminal portion 18. Also, the pad portion 17 is located inward in the first direction x with respect to the second terminal portions 18.

The second terminal portion 18 is located on the second side in the first direction x (the left side in FIG. 7) with respect to the die pad 12 of the lead 1A. The second terminal portion 18 extends toward the second side in the first direction x. The second terminal portions 15 of the lead 1B and the second terminal portion 18 of the lead 1C are arranged at intervals in the second direction y. The second terminal portions 15 is an example of the “terminal portion” that extends in a direction orthogonal to the thickness direction z (the first direction x in the illustrated example). The second terminal portion 18 has a reverse-surface mount portion 181. The reverse-surface mount portion 181 faces the second side in the thickness direction z (the lower side in FIG. 7). The reverse-surface mount portion 181 is exposed from the sealing resin 7. When the semiconductor device A10 is mounted on a circuit board, not shown, the reverse-surface mount portion 181 is bonded with a bonding material, such as solder. The bent portion 19 connects the pad portion 17 and the second terminal portion 18 and has a bent shape as viewed in the second direction y.

As shown in FIGS. 6, 7 and 9 to 17, the base materials 101 forming the leads 1A to 1C have first terminal-extending portions 103. In the present embodiment, the base material 101 of each of the leads 1A to 1C has a first terminal-extending portion 103. The base material 101 of the lead 1A includes a plurality of first terminal-extending portions 103 correspondingly to the plurality of first terminal portions 13. In the base material 101 of the lead 1A, each first terminal-extending portion a 103 is a portion forming corresponding first terminal portion 13. The base material 101 of the lead 1B includes a plurality of first terminal-extending portions 103 correspondingly to the plurality of second terminal portions 15. In the base material 101 of the lead 1B, each first terminal-extending portion 103 is a portion forming a corresponding second terminal portion 15. The base material 101 of the lead 1C includes a first terminal-extending portion 103 correspondingly to the second terminal portion 18. In the base material 101 of the lead 1C, the first terminal-extending portion 103 is a portion forming the second terminal portion 18.

Each first terminal-extending portion 103 is exposed from the sealing resin 7 and extends in a direction orthogonal to the thickness direction z (the first direction x in the present embodiment). In the present embodiment, each first terminal-extending portion 103 includes a first end portion 104, a first side wall 105, and a second side wall 115.

The first end portion 104 is located at the extremity in the direction in which the first terminal-extending portion 103 extends (the first direction x) and faces in the first direction x. In the present embodiment, the first end portion 104 is a flat surface facing in the first direction x. In the first terminal-extending portions 103 forming the first terminal portions 13, the first end portion 104 faces the first side in the first direction x. In the first terminal-extending portions 103 forming the second terminal portions 15 (18), the first end portion 104 faces the second side in the first direction x.

The first side wall 105 faces in a direction (the second direction y in the present embodiment) orthogonal to the direction in which the first terminal-extending portion 103 extends (the first direction x), as viewed in the thickness direction z. In the present embodiment, the first side wall 105 faces a first side in the second direction y. As shown in FIGS. 9, 10, 11 and 13, the first side wall 105 includes a first side portion 106, a second side portion 107, and a third side portion 108. The first side portion 106 is located closer to the first end portion 104 in the first direction x. The second side portion 107 is located closer to the sealing resin 7 in the first direction x. The third side portion 108 is located between the first side portion 106 and the second side portion 107 in the first direction x.

As shown in FIGS. 9 and 10, the first side portion 106 and the second side portion 107 are located on a second side in the second direction y (the left side in FIGS. 9 and 10) with respect to the third side portion 108. The first side portion 106 extends toward the second side in the second direction y as proceeding away from the third side portion 108 in the first direction x, and has an arcuate, concave shape as viewed in the thickness direction z.

In the present embodiment, the second side portion 107 includes a second-side first part 107a and a second-side second part 107b. The second-side first part 107a is a flat surface facing the first side in the second direction y (the right side in FIGS. 9 and 10). The second-side second part 107b is connected to the second-side first part 107a and the third side portion 108 and extends toward the second side in the second direction y as proceeding away from the third side portion 108 in the first direction x. The second-side second part 107b has an arcuate, concave shape as viewed in the thickness direction z. In the present embodiment, the third side portion 108 is a flat surface facing the first side in the second direction y (the right side in FIGS. 9 and 10).

Of the first end portion 104 and the first side wall 105 (the first side portion 106, the second side portion 107, and the third side portion 108) , the first end portion 104, the first side portion 106, and the second side portion 107 are covered with the metal layer 102. The metal layer 102 is provided at locations avoiding the third side portion 108, and the third side portion 108 is not covered with the metal layer 102. The third side portion 108 is a cut surface formed by cutting, for example, a metal plate (lead frame) used for manufacturing the semiconductor device, where the surface of the base material 101 is exposed. In FIGS. 11 and 13, the cut surface formed by cutting a lead frame is hatched.

In the present embodiment, the lengths of the above-described portions of the first side wall 105 in the first direction x have the following relationship. As shown in FIGS. 11 and 13, the first dimension L1, which is the length of the first side portion 106 in the first direction x, is smaller than the second dimension L2, which is the length of the second side portion 107 in the first direction x. The ratio of the length L11 of the third side portion 108 in the first direction x to the length L10 of the first side wall 105 in the first direction x is in the range of 0.25 to 0.7 times.

The second side wall 115 faces a side opposite to the side that the first side wall 105 faces in the second direction y. In the present embodiment, the second side wall 115 faces the second side in the second direction y. As shown in FIGS. 9, 10, 12 and 14, the second side wall 115 includes a fourth side portion 116, a fifth side portion 117, and a sixth side portion 118. The fourth side portion 116 is located closer to the first end portion 104 in the first direction x. The fifth side portion 117 is located closer to the sealing resin 7 in the first direction x. The sixth side portion 118 is located between the fourth side portion 116 and the fifth side portion 117 in the first direction x.

As shown in FIGS. 9 and 10, the fourth side portion 116 and the fifth side portion 117 are located on the first side in the second direction y (the right side in FIGS. 9 and 10) with respect to the sixth side portion 118. The fourth side portion 116 extends toward the first side in the second direction y as proceeding away from the sixth side portion 118 in the first direction x, and has an arcuate, concave shape as viewed in the thickness direction z.

In the present embodiment, the fifth side portion 117 includes a fifth-side first part 117a and a fifth-side second part 117b. The fifth-side first part 117a is a flat surface facing the second side in the second direction y (the left side in FIGS. 9 and 10). The fifth-side second part 117b is connected to the fifth-side first part 117a and the sixth side portion 118 and extends toward the first side in the second direction y as proceeding away from the sixth side portion 118 in the first direction x. The fifth-side second part 117b has an arcuate, concave shape as viewed in the thickness direction z. In the present embodiment, the sixth side portion 118 is a flat surface facing the second side in the second direction y (the left side in FIGS. 9 and 10).

Of the second side wall 115 (the fourth side portion 116, the fifth side portion 117, and the sixth side portion 118) , the fourth side portion 116 and the fifth side portion 117 are covered with the metal layer 102. The metal layer 102 is provided at locations avoiding the sixth side portion 118, and the sixth side portion 118 is not covered with the metal layer 102. The sixth side portion 118 is a cut surface formed by cutting, for example, a metal plate (lead frame) used for manufacturing the semiconductor device, where the surface of the base material 101 is exposed. In FIGS. 12 and 14, the cut surface formed by cutting a lead frame is hatched.

In the present embodiment, the lengths of the above-described portions of the second side wall 115 have the following relationship. As shown in FIGS. 12 and 14, the third dimension L3, which is the length of the fourth side portion 116 in the first direction x, is smaller than the fourth dimension L4, which is the length of the fifth side portion 117 in the first direction x. The ratio of the length L13 of the sixth side portion 118 in the first direction x to the length L12 of the second side wall 115 in the first direction x is in the range of 0.25 to 0.7 times.

The metal layer 102 covers portions of the first terminal-extending portion 103 except the third side portion 108 and the sixth side portion 118. In the area around the extremity of the first terminal-extending portion 103, the metal layer 102 covers the first end portion 104, the first side portion 106 of the first side wall 105 connected to the first end portion 104, and the fourth side portion 116 of the second side wall 115 connected to the first end portion 104.

FIG. 18 is a plan view showing a part of the lead frame used in manufacturing the semiconductor device A10. In FIG. 18, the lead frame 9 before cutting is indicated by imaginary lines (dash-double dot lines). In the lead frame 9, the entire surface of the base material is covered with a metal layer. The lead frame 9 has a bar-shaped part 91 extending in the second direction y to intersect the first terminal portions 13 at their intermediate sections in the first direction x. As shown in FIG. 18, the bar-shaped part 91 is formed with a plurality of recesses 911, recesses 912, recesses 913, and recesses 914. Each recess 911 has a semicircular shape corresponding to the first side portion 106 of the first terminal-extending portion 103. Each recess 912 has a semicircular shape corresponding to the second-side second part 107b of the first terminal-extending portion 103. Each recess 913 has a semicircular shape corresponding to the fourth side portion 116 of the first terminal-extending portion 103. Each recess 914 has a semicircular shape corresponding to the fifth-side second part 117b of the first terminal-extending portion 103. The bar-shaped part 91 of the lead frame 9 is cut along an xz-plane defined by the first direction x and the thickness direction z at respective centers of the recess 911 and the recess 912 in the second direction y, and also cut along an xz plane at respective centers of the recess 913 and the recess 914 in the second direction y. As a result, a plurality of first terminal-extending portions 103, in which the third side portion 108 and the sixth side portion 118 are the cut surfaces (surface of the base material 101) , are formed. Though the illustration and description are omitted, the first terminal-extending portions 103 (the third side portions 108 and the sixth side portions 118) of the second terminal portions 15 and 18 are formed by the same process as that of the first terminal portions 13.

The semiconductor element 2 is an element that exerts an electrical function of the semiconductor device A10. The type of the semiconductor element 2 is not particularly limited. In the present embodiment, the semiconductor element 2 is configured as a transistor. As shown in FIGS. 3 and 6 to 8, the semiconductor element 2 has an element body 20, a first electrode 21, a second electrode 22, and a third electrode 23.

The element body 20 is rectangular as viewed in the thickness direction z. The element body 20 has an element obverse surface 201 and an element reverse surface 202. The element obverse surface 201 and the element reverse surface 202 face away from each other in the thickness direction z. The element obverse surface 201 faces the same side as the side that the first surface 121 of the die pad 12 faces in the thickness direction z. Thus, the element reverse surface 202 faces the first surface 121.

The first electrode 21 and the third electrode 23 are disposed on the element obverse surface 201. The second electrode 22 is disposed on the element reverse surface 202. The first electrode 21, the second electrode 22, and the third electrode 23 are made of copper or aluminum (Al) , or an alloy of these, for example. In the present embodiment, the first electrode 21 is a source electrode, the second electrode 22 is a drain electrode, and the third electrode 23 is a gate electrode.

In the present embodiment, the first electrode 21 covers most of the element obverse surface 201. Specifically, the first electrode 21 is disposed over the area excluding the peripheral portion and a single corner (the lower right corner in FIG. 3) of the rectangular element obverse surface 201. The first electrode 21 has a first-electrode pad portion 212. The first-electrode pad portion 212 is located inward of the insulating part 3 as viewed in the thickness direction z. The third electrode 23 is disposed at a corner (the lower right corner in FIG. 3) of the element obverse surface 201. The second electrode 22 covers the entire surface (or almost the entire surface) of the element reverse surface 202.

The second electrode 22 is conductively bonded to the first surface 121 (die pad 12) via the conductive bonding material 62. The conductive bonding material 62 conductively bonds the die pad 12 and the second electrode 22. The conductive bonding material 62 is solder, for example.

The semiconductor device A10 is provided with a wire 65. The wire 65 is conductively bonded to the third electrode 23 and the pad portion 17 of the lead 1C. The wire 65 conductively bonds the third electrode 23 and the lead 1C.

As shown in FIGS. 3 and 6 to 8, the insulating part 3 is disposed across the first electrode 21 and the element obverse surface 201. The insulating part 3 is in the form of a frame overlapping with the periphery of the first electrode 21 as viewed in the thickness direction z. The outer edge of the insulating part 3 is located close to the periphery of the element obverse surface 201 as viewed in the thickness direction z. The region of the first electrode 21 that is located inward of the inner edge of the insulating part 3 as viewed in the thickness direction z is the first-electrode pad portion 212. The insulating part 3 has, for example, a configuration in which a plurality of insulating layers are formed on top of each other. For example, the insulating part 3 has a configuration in which an upper insulating layer made of a resin material is laminated on a lower insulating layer made of a nitride. Examples of the nitride forming the lower insulating layer include SiN, SiON, and SiO₂. Examples of the resin material forming the upper insulating layer include polyimide resin.

As shown in FIGS. 3 and 6 to 8, the metal laminate part 4 extends over the first electrode 21 and the insulating part 3, and has, for example, a configuration in which a plurality of metal layers are formed on top of each other. For example, the metal laminate part 4 has a configuration in which a metal layer containing titanium (Ti), a metal layer containing nickel, and a metal layer containing silver (Ag) are laminated in this order.

As shown in FIGS. 3 and 6, the conductive member 5 is bonded to the first electrode 21 of the semiconductor element 2 and the lead 1B. The conductive member 5 is made of a metal plate. The metal is copper or a copper alloy. The conductive member 5 is formed by punching or bending the metal plate. In the present embodiment, the conductive member 5 includes an element-side bond portion 51, a lead-side bond portion 52, and an intermediate portion 53. As shown in FIG. 6, the element-side bond portion 51, the lead-side bond portion 52, and the intermediate portion 53 are connected while bending as appropriate as viewed in the second direction y.

The element-side bond portion 51 is bonded to the first-electrode pad portion 212 of the first electrode 21 via the conductive bonding material 61. The conductive bonding material 61 conductively bonds the element-side bond portion 51 (conductive member 5) and the first-electrode pad portion 212. The conductive bonding material 1 is solder, for example.

As shown in FIGS. 6 to 8, the element-side bond portion 51 is formed with protrusions 511 and recesses 512. The protrusions 511 protrude downward (toward the second side in the thickness direction z) from the lower surface of the element-side bond portion 51 (the surface facing the element obverse surface 201). In the illustrated example, two protrusions 511 are provided at intervals in the first direction x, and each protrusion 511 extends in the second direction y with a constant width. The recesses 512 are recessed upward (toward the first side in the thickness direction z) from the lower surface of the element-side bond portion 51. In the illustrated example, two recesses 512 are provided at intervals in the second direction y, and each recess 512 extends in the first direction second direction x with a constant width.

When the first-electrode pad portion 212 and the element-side bond portion 51 are bonded to each other, the protrusions 511 are pressed against the first-electrode pad portion 212 side while a sufficient amount of conductive bonding material 61 is present around the protrusions 511. Thus, the conduction between the element-side bond portion 51 and the first-electrode pad portion 212 is properly maintained. The lower surface of the element-side bond portion 51 has recesses 512. Therefore, when voids are present in the conductive bonding material 61, such voids can be trapped in the recesses 512, whereby the voids in the conductive bonding material 61 can be reduced. Instead of the illustrated recesses 512, through-holes penetrating the element-side bond portion 51 in the thickness direction z may be formed to reduce voids.

The lead-side bond portion 52 is bonded to the pad portion 14 of the lead 1B via the conductive bonding material 63. The conductive bonding material 63 conductively bonds the lead-side bond portion 52 (conductive member 5) and the pad portion 14 (lead 1B). The conductive bonding material 63 is solder, for example. As shown in FIG. 6, the lead-side bond portion 52 has a protruding part located on the second side in the thickness direction z (the lower side in the figure) with respect to the surrounding portions. When the pad portion 14 and the lead-side bond portion 52 are bonded to each other, the protruding part is pressed against the pad portion 14 while a sufficient amount of conductive bonding material 63 is present around the protruding part. Thus, the conduction between the lead-side bond portion 52 and the pad portion 14 is properly maintained.

The intermediate portion 53 is located between the element-side bond portion 51 and the lead-side bond portion 52 in the first direction x. The intermediate portion 53 is connected to the element-side bond portion 51 and the lead-side bond portion 52.

Incidentally, instead of the above-described conductive member 5, a plurality of wires may be conductively bonded to the first electrode 21 and the pad portion 14 of the lead 1B. Also, unlike the present embodiment, the semiconductor device of the present disclosure may not include the insulating part 3 and the metal laminate part 4.

The sealing resin 7 covers a part of each of the leads 1A, 1B and 1C, the semiconductor element 2, the insulating part 3, the metal laminate part 4, the conductive member 5, and the wire 65. Specifically, the sealing resin 7 covers at least a part of the die pad 12 of the lead 1A, and a part of each of the first terminal portions 13, the second terminal portions 15, and the second terminal portion 18. The sealing resin 7 is made of a black epoxy resin, for example.

As shown in FIGS. 1, 2, and 4 to 8, the sealing resin 7 has a resin obverse surface 71, a resin reverse surface 72, and resin side surfaces 73 to 76. The resin obverse surface 71 and the resin reverse surface 72 face away from each other in the thickness direction z. The resin obverse surface 71 faces the first side in the thickness direction z, and faces the same side as the side that the element obverse surface 201 and the first surface 121 face. The resin reverse surface 72 faces the second side in the thickness direction z, and faces the same side as the side that the element reverse surface 202 and the reverse-surface mount portion 122 face.

Each of the resin side surfaces 73 to 76 is connected to the resin obverse surface 71 and the resin reverse surface 72 and located between the resin obverse surface 71 and the resin reverse surface 72 in the thickness direction z. The resin side surface 73 and the resin side surface 74 face away from each other in the first direction x. The resin side surface 73 faces the first side in the first direction x, and the resin side surface 74 faces the second side in the first direction x. The resin side surface 75 and the resin side surface 76 face away from each other in the second direction y. The resin side surface 75 faces the first side in the second direction y, and the resin side surface 76 faces the second side in the second direction y. As shown in FIG. 1, a part of each of the first terminal portions 13 protrudes from the resin side surface 73. Also, a part of each of the second terminal portions 15 and the second terminal portion 18 protrudes from the resin side surface 74. In the illustrated example, each of the resin side surfaces 73 to 76 is sightly inclined with respect to the thickness direction z. The shape of the sealing resin 7 shown in FIGS. 1, 2 and 4 to 8 is an example. The shape of the sealing resin 7 is not limited to the illustrated one.

The effects of the present embodiment will be described.

In the semiconductor device A10, each of the leads 1A to 1C includes a base material 101 and metal layer 102 covering the base material 101. The base material 101 includes a first terminal-extending portion 103 that forms the first terminal portion 13, the second terminal portion 15 or the second terminal portion 18. The first terminal-extending portion 103 is exposed from the sealing resin 7 to extend in the first direction x, and includes a first end portion 104 facing in the first direction x and a first side wall 105 facing in the second direction y. The first side wall 105 includes a first side portion 106, a second side portion 107, and a third side portion 108. The first side portion 106 is located closer to the first end portion 104 in the first direction x and connected to the first end portion 104. The second side portion 107 is located closer to the sealing resin 7. The third side portion 108 is located between the first side portion 106 and the second side portion 107. The metal layer 102 covers the first end portion 104, the first side portion 106, and the second side portion 107, and is provided at locations avoiding the third side portion 108.

According to the above configuration, because the first end portion 104, which is the extremity of the first terminal-extending portion 103, and the first side portion 106 of the first side wall 105 connected to the first end portion 104 are covered with the metal layer 102, cutting the lead frame 9 during the manufacture of the semiconductor device A10 does not generate metal burrs at these portions. This eliminates the likelihood that metal burrs generated by cutting the lead frame 9 protrude from the extremity of the first terminal portions 13, the second terminal portions 15, and the second terminal portion 18. Therefore, a decrease in the reliability of mounting the semiconductor device A10 on a circuit board, for example, is suppressed.

The metal layer 102 covers the area around the extremity (the first end portion 104 and the first side portion 106) of the first terminal-extending portion 103. The metal layer 102 is a plating layer and has a higher solder wettability than that of the base material 101. Therefore, when the semiconductor device A10 is mounted on a circuit board with solder, the end surfaces and the side surfaces connected thereto of the first terminal portions 13, 15 and 18 are covered with solder. This increases the mounting strength of the semiconductor device A10 and improves the mounting reliability of the semiconductor device A10.

In the present embodiment, the first terminal-extending portion 103 includes a second side wall 115. The second side wall 115 faces a side opposite to the side that the first side wall 105 faces in the second direction y (the second side in the second direction y). The second side wall 115 includes a fourth side portion 116, a fifth side portion 117, and a sixth side portion 118. The fourth side portion 116 is located closer to the first end portion 104 in the first direction x and connected to the first end portion 104. The fifth side portion 117 is located closer to the sealing resin 7. The sixth side portion 118 is located between the fourth side portion 116 and the fifth side portion 117. The metal layer 102 covers the fourth side portion 116 and the fifth side portion 117, and is provided at locations avoiding the sixth side portion 118. According to such a configuration, because the first end portion 104, which is the extremity of the first terminal-extending portion 103, the first side portion 106 of the first side wall 105 connected to the first end portion 104, and the fourth side portion 116 of the second side wall 115 connected to the first end portion 104 are covered with the metal layer 102, cutting the lead frame 9 during the manufacture of the semiconductor device A10 does not generate metal burrs at these portions. This further eliminates the likelihood that the metal burrs generated by cutting the lead frame 9 protrude from the extremity of the first terminal portions 13, the second terminal portions 15, and the second terminal portion 18. Therefore, a decrease in the reliability of mounting the semiconductor device A10 on a circuit board, for example, is suppressed.

The ratio of the length L11 of the third side portion 108 in the first direction x to the length L10 of the first side wall 105 in the first direction x and the ratio of the length L13 of the sixth side portion 118 in the first direction x to the length L12 of the second side wall 115 in the first direction x are in the range of 0.25 to 0.7 times, which is relatively small. With such a configuration, the areas of the third side portion 108 and the sixth side portion 118, which are the cut surfaces of the lead frame 9, can be made small. This reduces the load during the cutting of the lead frame 9 and suppresses generation of metal burrs. This is favorable for suppressing a decrease in the mounting reliability of the semiconductor device A10.

The first side portion 106 and the second-side second part 107b extend toward the second side in the second direction y as proceeding away from the third side portion 108 in the first direction x. The fourth side portion 116 and the fifth-side second part 117b extend toward the first side in the second direction y as proceeding away from the sixth side portion 118 in the first direction x. Such a shape is formed by cutting the lead frame 9 at the centers of concave recesses, i.e., the recesses 911 and 912 and the recesses 913 and 914. This reduces the load during the cutting of the lead frame 9 and suppresses generation of metal burrs. This is favorable for suppressing a decrease in the mounting reliability of the semiconductor device A10.

Of the first terminal portions 13, those located at one end and at the other end in the second direction y each have the first terminal-extending portion 103. Also, of the second terminal portions 15 and 18, those located at one end and at the other end in the second direction y each have the first terminal-extending portion 103. Such a configuration effectively increases the mounting strength at the four corners of the semiconductor device A10. In the present embodiment, all of the first terminal portions 13, the second terminal portions 15, and the second terminal portion 18 of the semiconductor device A10 have the first terminal-extending portion 103. This further increases the mounting strength of the semiconductor device A10.

First variation of the first embodiment:

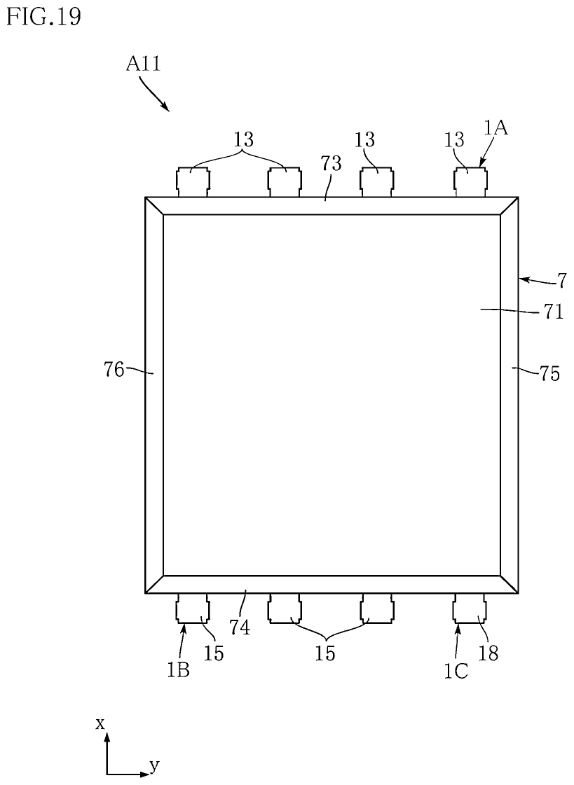

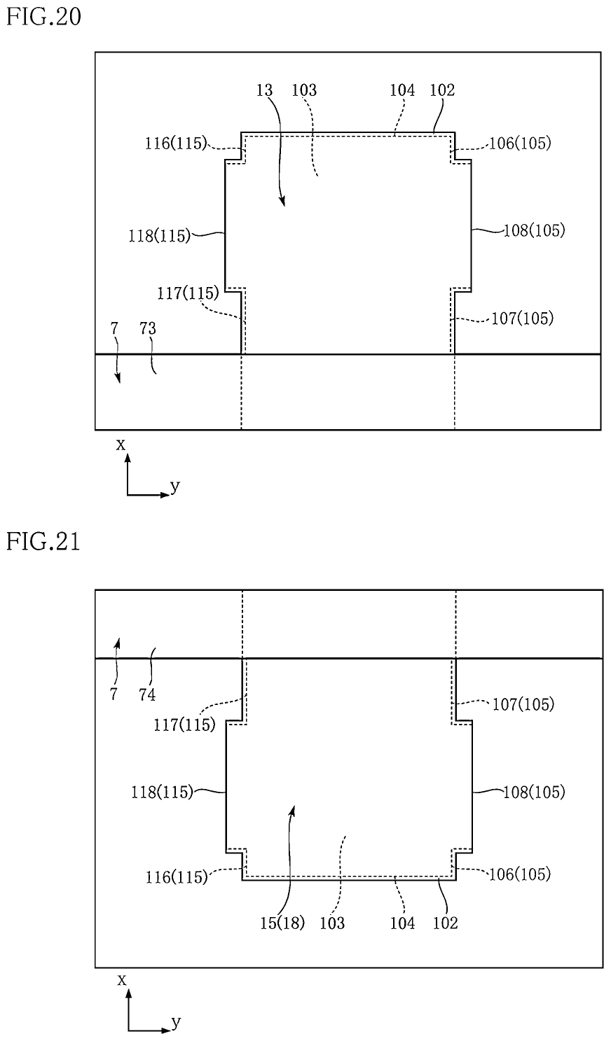

FIGS. 19 to 21 show a semiconductor device All according to a first variation of the first embodiment. FIG. 19 is a plan view of the semiconductor device A11. FIG. 20 is a partial enlarged view of FIG. 19 (enlarged view of the area around a first terminal portion 13). FIG. 20 is a partial enlarged view of FIG. 19 (enlarged view of the area around a second terminal portion 15 or 18). In FIG. 19 and the subsequent figures, the elements that are identical or similar to those of the semiconductor device A10 of the above-described embodiment are denoted by the same reference signs as those of the above-described embodiment, and the descriptions thereof are omitted as appropriate.

In the semiconductor device All of the present variation, the configurations of the first side wall 105 and the second side wall 115 in each of the first terminal portions 13, the second terminal portions 15, and the second terminal portion 18 differ from those of the above-described embodiment. In the present variation, the first side portion 106 and the second side portion 107 are stepped toward the second side in the second direction y with respect to the third side portion 108. Likewise, the fourth side portion 116 and the fifth side portion 117 are stepped toward the first side in the second direction y with respect to the sixth side portion 118.

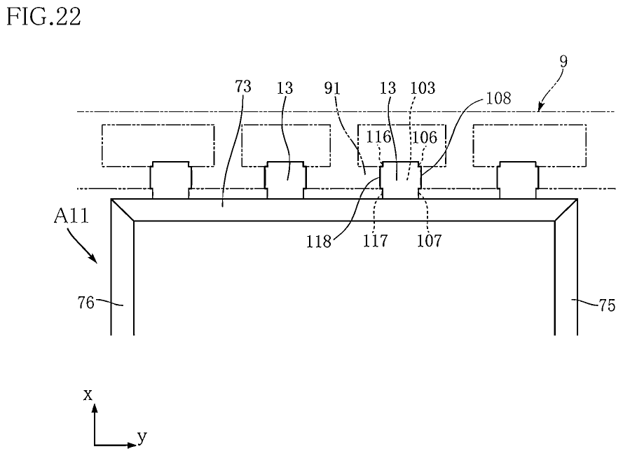

FIG. 22 is a plan view showing a part of the lead frame used in manufacturing the semiconductor device All. In FIG. 22, the lead frame 9 before cutting is indicated by imaginary lines (dash-double dot lines). In the lead frame 9, the entire surface of the base material is covered with a metal layer. The lead frame 9 has a bar-shaped part 91 extending in the second direction y to intersect the first terminal sections in the first portions 13 at their intermediate direction x. The width of the bar-shaped part 91 in the first direction x is made relatively small. The bar-shaped part 91 of the lead frame 9 is cut along an xz-plane at locations near the first side portion 106 and the second side portion 107 and at locations near the fourth side portion 116 and the fifth side portion 117. As a result, a plurality of first terminal-extending portions 103, in which the third side portion 108 and the sixth side portion 118 surfaces (surface of the base material 101) , are formed. Though the illustration and description are omitted, the first terminal-extending portions 103 (the third side portions 108 and the sixth side portions 118) of the second terminal portions 15 and 18 are formed by the same process as that of the first terminal portions 13.

According to the semiconductor device All of the present variation, because the first end portion 104, which is the extremity of the first terminal-extending portion 103, and the first side portion 106 of the first side wall 105 connected to the first end portion 104 are covered with the metal layer 102, cutting the lead frame 9 during the manufacture of the semiconductor device All does not generate metal burrs at these portions. This eliminates the likelihood that the metal burrs generated by cutting the lead frame 9 protrude from the extremity of the first terminal portions 13, the second terminal portions 15, and the second terminal portion 18. Therefore, a decrease in the reliability of mounting the semiconductor device A10 on a circuit board, for example, is suppressed. Additionally, the same effects as those of the above-described embodiment are provided due to the configuration in common with the semiconductor device A10 of the above-described embodiment.

Second variation of the first embodiment:

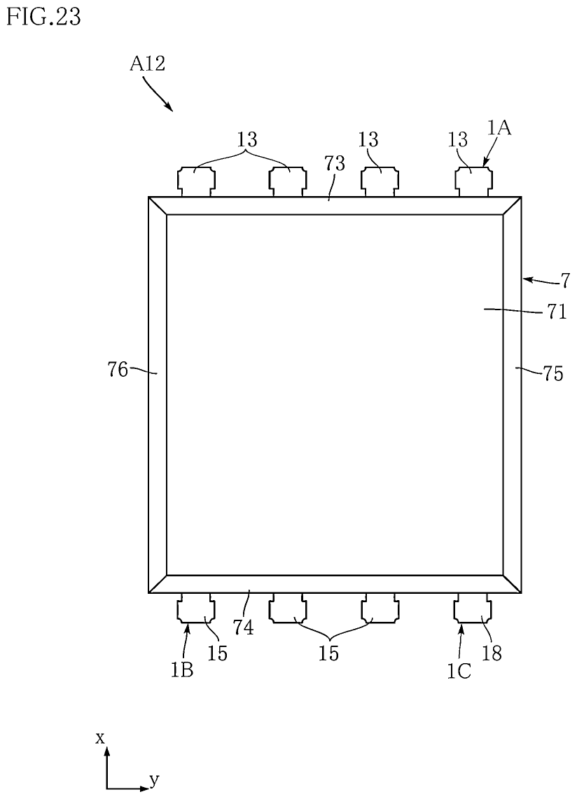

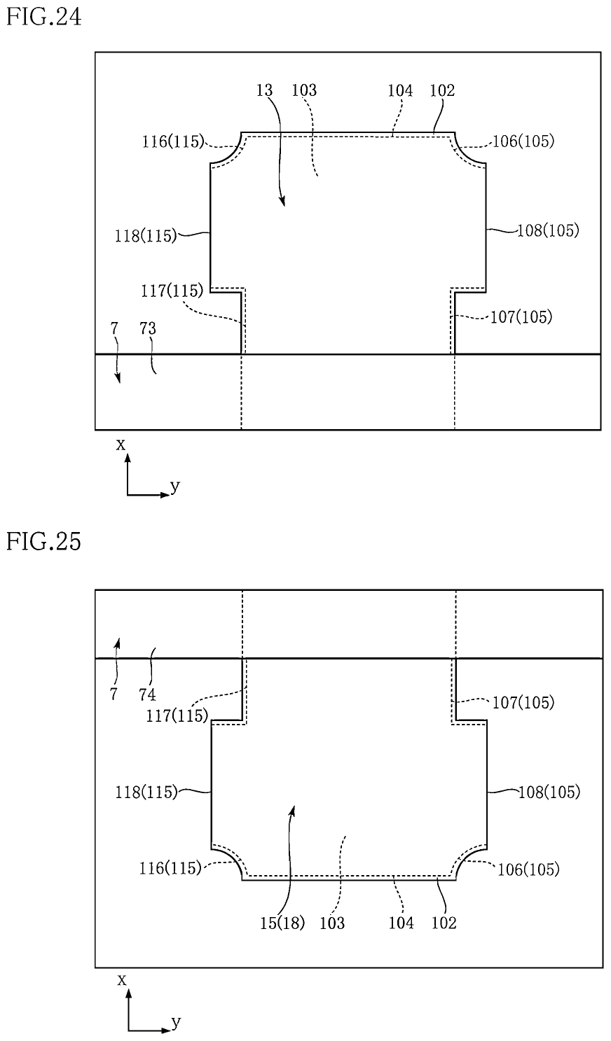

FIGS. 23 to 25 show a semiconductor device A12 according to a second variation of the first embodiment. FIG. 23 is a plan view of the semiconductor device A12. FIG. 24 is a partial enlarged view of FIG. 23 (enlarged view of the area around a first terminal portion 13). FIG. 25 is a partial enlarged view of FIG. 23 (enlarged view of the area around a second terminal portion 15 or 18).

In the semiconductor device A12 of the present variation, the configurations of the first side wall 105 and the second side wall 115 in each of the first terminal portions 13, the second terminal portions 15, and the second terminal portion 18 differ from those of the above-described embodiment. In the present variation, the second side portion 107 is stepped toward the second side in the second direction y with respect to the third side portion 108. Likewise, the fifth side portion 117 is stepped toward the first side in the second direction y with respect to the sixth side portion 118.

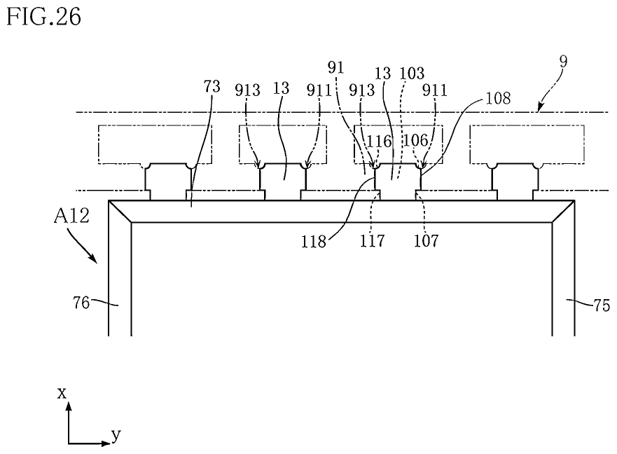

FIG. 26 is a plan view showing a part of the lead frame used in manufacturing the semiconductor device A12. In FIG. 26, the lead frame 9 before cutting is indicated by imaginary lines (dash-double dot lines). In the lead frame 9, the entire surface of the base material is covered with a metal layer. The lead frame 9 has a bar-shaped part 91 extending in the second direction y to intersect the first terminal portions 13 at their intermediate sections in the first direction x. As shown in FIG. 26, the bar-shaped part 91 is formed with a plurality of recesses 911 and recesses 913. Each recess 911 has a semicircular shape corresponding to the first side portion 106 of the first terminal-extending portion 103. Each recess 913 has a semicircular shape corresponding to the fourth side portion 116 of the first terminal-extending portion 103. The bar-shaped part 91 of the lead frame 9 is cut along an xz-plane at the center of the recess 911 in the second direction y, and also cut along the an xz-plane at the center of the recess 913 in the second direction y. As a result, a plurality of first terminal-extending portions 103 in which the third side portion 108 and the sixth side portion 118 are the cut surfaces (surface of the base material 101) are formed. Though the illustration and description are omitted, the first terminal-extending portions 103 (the third side portions 108 and the sixth side portions 118) of the second terminal portions 15 and 18 are formed by the same process as that of the first terminal portions 13.

According to the semiconductor device A12 of the present variation, because the first end portion 104, which is the extremity of the first terminal-extending portion 103, and the first side portion 106 of the first side wall 105 connected to the first end portion 104 are covered with the metal layer 102, cutting the lead frame 9 during the manufacture of the semiconductor device A12 does not generate metal burrs at these portions. This eliminates the likelihood that the metal burrs generated by cutting the lead frame 9 protrude from the extremity of the first terminal portions 13, the second terminal portions 15, and the second terminal portion 18. Therefore, a decrease in the reliability of mounting the semiconductor device A10 on a circuit board, for example, is suppressed. Additionally, the same effects as those of the above-described embodiment are provided due to the configuration in common with the semiconductor device A10 of the above-described embodiment.

### Second Embodiment

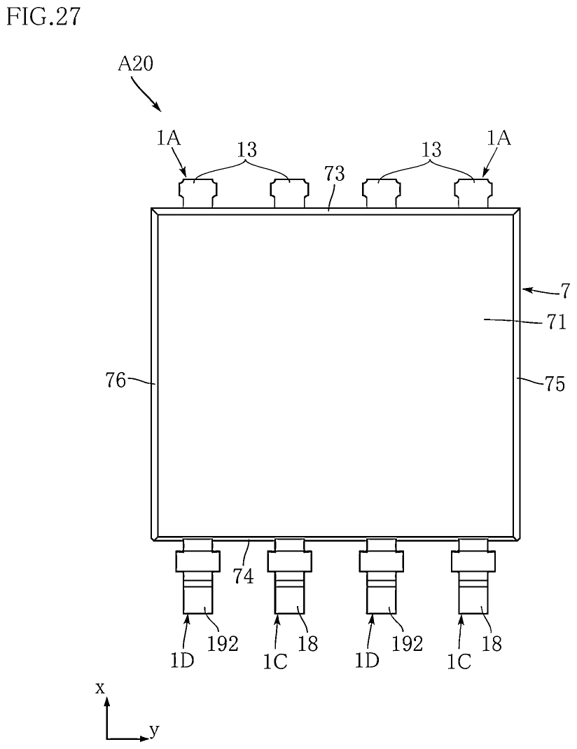

FIGS. 27 to 35 show a semiconductor device A20 according to a second embodiment of the present disclosure. The semiconductor device A20 includes a plurality of leads 1A, 1C and 1D, a semiconductor element 2, conductive bonding materials 61, 62 and 64, and a sealing resin 7.

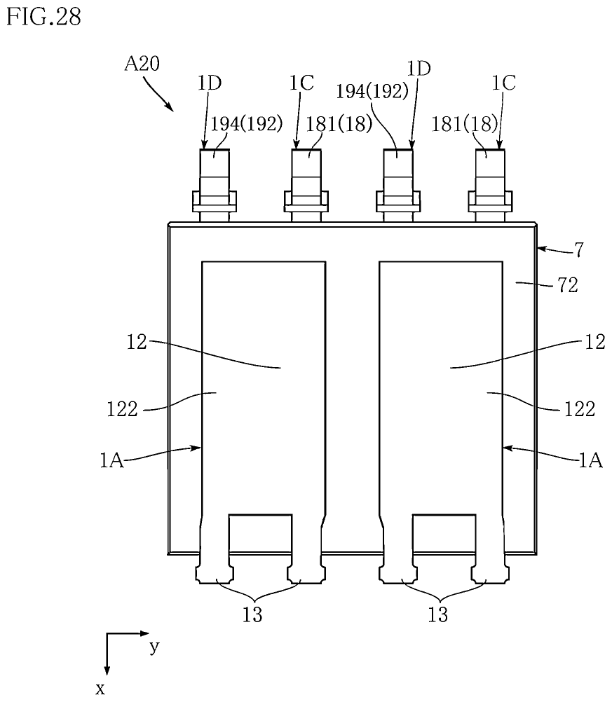

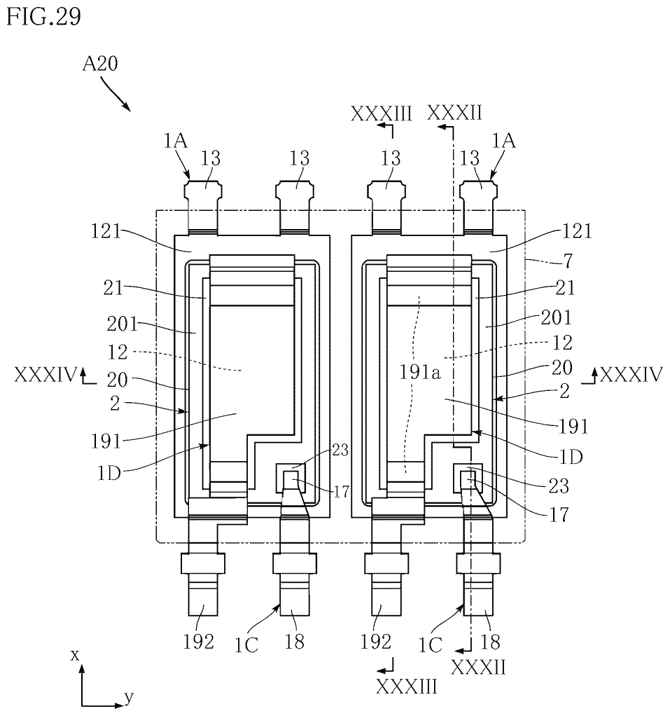

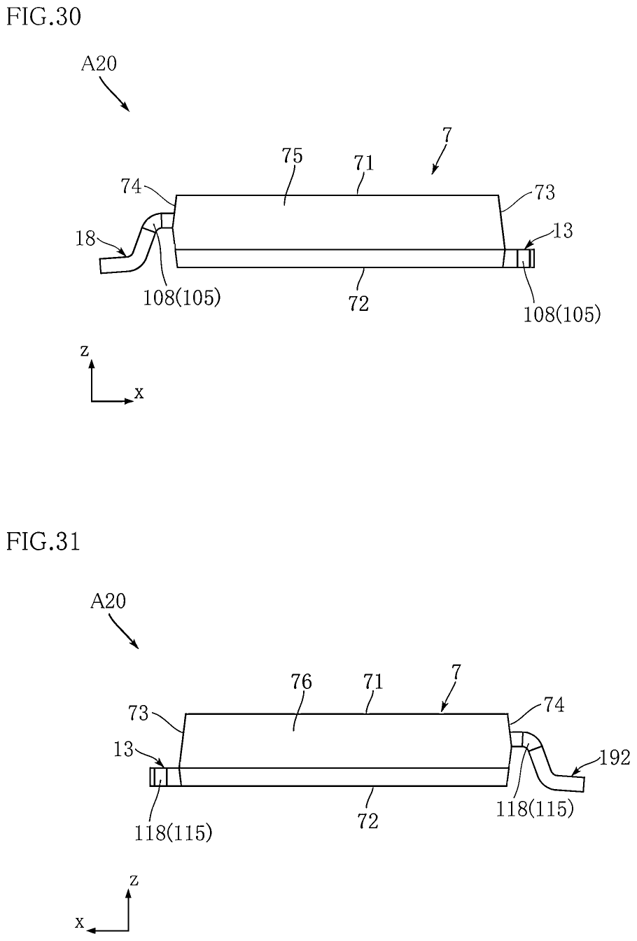

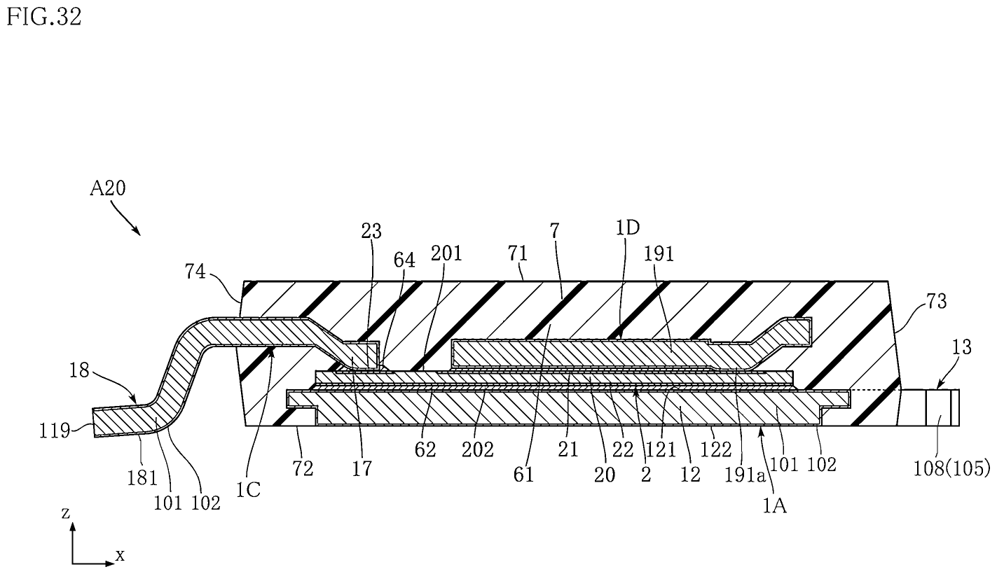

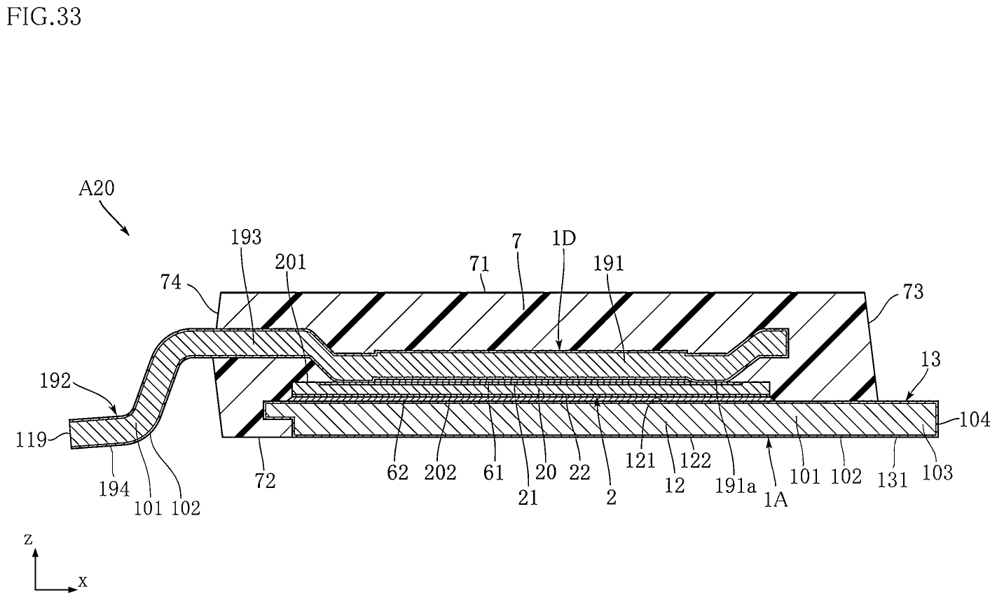

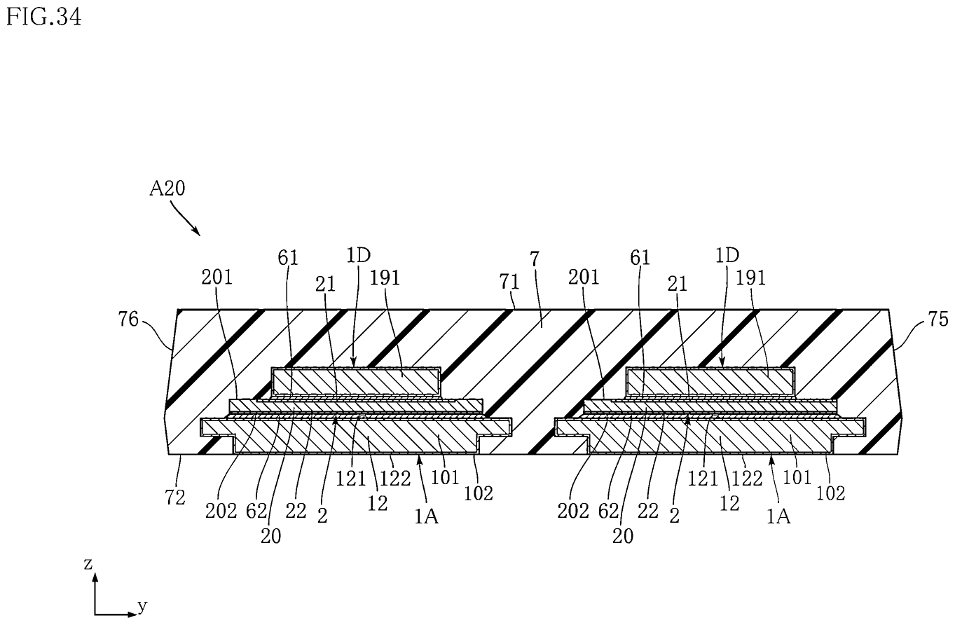

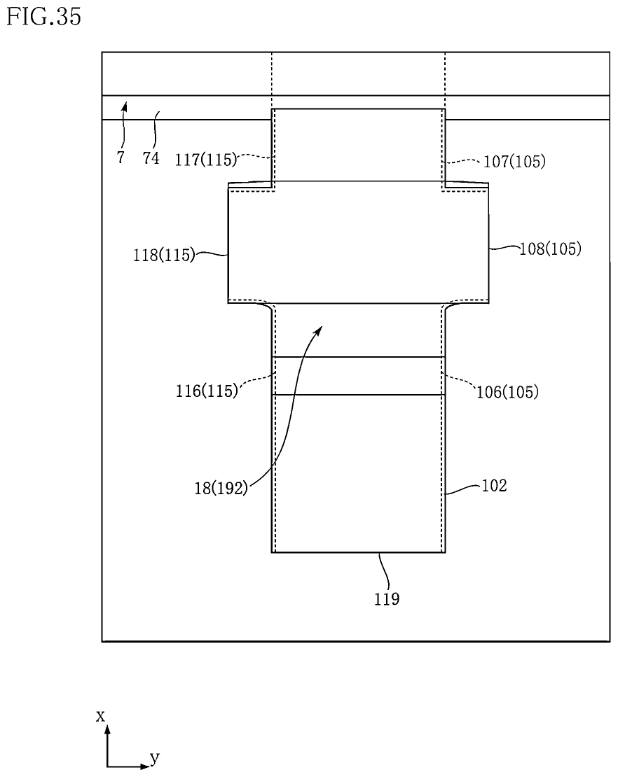

FIG. 27 is a plan view of the semiconductor device A20. FIG. 28 is a bottom view of the semiconductor device A20. FIG. 29 is a plan view of the semiconductor device A20. FIG. 30 is a right side view of the semiconductor device A20. FIG. 31 is a left side view of the semiconductor device A20. FIG. 32 is a sectional view taken along line XXXII-XXXII in FIG. 29. FIG. 33 is a sectional view taken along line XXXIII-XXXIII in FIG. 29. FIG. 34 is a sectional view taken along line XXXIV-XXXIV in FIG. 29. FIG. 35 is a partial enlarged view of FIG. 27 (enlarged view of the area around a second terminal portion 18 or 192, described later). In FIG. 29, the sealing resin 7 is transparent for the convenience of understanding.

The semiconductor device A20 of the present embodiment has two semiconductor elements 2, and various changes have been made accordingly. The two semiconductor elements 2 are disposed in pairs on the first side in the second direction y (the right side in FIG. 29) and on the second side in the second direction y (the left side in FIG. 29). In the semiconductor device A20, a semiconductor element 2, leads 1A, 1C and 1D, and conductive bonding materials 61, 62 and 64 are disposed on each of the first side and the second side in the second direction y. The configurations of the leads 1A, 1C and 1D, the semiconductor element 2, and the conductive bonding materials 61, 62 and 64 on the first side in the second direction y (the right side in FIG. 29) and the configurations of the leads 1A, 1C and 1D, the semiconductor element 2, and the conductive bonding materials 61, 62 and 64 on the second side in the second direction y are substantially the same. In the semiconductor device A20, each of the semiconductor elements 2 is a power semiconductor chip with a switching function, such as a MOSFET (Metal Oxide Semiconductor Field The two Effect Transistor). semiconductor elements are used in combination in a circuit such as a synchronous rectifier circuit or a half bridge circuit.

As shown in FIGS. 29 and 32 to 34, the lead 1A has a die pad 12 and a plurality of (two in the present embodiment) first terminal portions 13. In the present embodiment, the configuration of each first terminal portion 13 is substantially the same as that of the first terminal portions 13 of the semiconductor device A10 according to the first embodiment. Thus, the base material 101 of the lead 1A includes a plurality of first terminal-extending portions 103 correspondingly to the plurality of first terminal portions 13. Though the illustration and description are omitted, each first terminal-extending portion 103 includes a first end portion 104, a first side wall 105, and a second side wall 115. The first side wall 105 includes a first side portion 106, a second side portion 107, and a third side portion 108, similarly to those shown in FIGS. 9 and 11 referred to in relation to the semiconductor device A10. The second side wall 115 has a fourth side portion 116, a fifth side portion 117, and a sixth side portion 118, similarly to those shown in FIGS. 9 and 12 referred to in relation to the semiconductor device A10. Though the illustration and description are omitted, the first terminal-extending portions 103 (the third side portions 108 and the sixth side portions 118) of the first terminal portions 13 are formed by the same process as that of the first terminal portions 13 of the above-described semiconductor device A10.

As shown in FIGS. 29 and 32, the lead 1C has a pad portion 17 and a second terminal portion 18. The pad portion 17 is located inward in the first direction x with respect to the second terminal portions 18. The pad portion 17 is bonded to the third electrode 23 of the semiconductor element 2 via the conductive bonding material 64. The conductive bonding material 64 conductively bonds the pad portion 17 (the lead 1C) and the third electrode 23. The second terminal portion 18 is located on the second side in the first direction X (the left side in FIG. 32) with respect to the die pad 12 of the lead 1A. In the present embodiment, the second terminal portion 18 is exposed from the sealing resin 7 and extends toward the second side in the first direction x while bending in the middle.

As shown in FIGS. 32 to 34, the lead 1D has an element-side bond portion 191, a second terminal portion second terminal portion 192, and an intermediate portion 193. The element-side bond portion 191 is bonded to the first electrode 21 via the conductive bonding material 61. The conductive bonding material 61 conductively bonds the element-side bond portion 191 (the lead 1D) and the first electrode 21.

As shown in FIGS. 32 and 33, the element-side bond portion 191 is formed with protrusions 191a. The protrusions 191a protrude downward (toward the second side in the thickness direction z) from the lower surface (the surface facing the element obverse surface 201) of the element-side bond portion 191. In the illustrated example, two protrusions 191a are provided at intervals in the first direction x, and each protrusion 191a extends in the second direction y with a constant width. When the first electrode 21 and the element-side bond portion 191 are bonded to each other, the element-side bond portion 191 is pressed against the first electrode 21 side while a sufficient amount of conductive bonding material 61 is present around the protrusion 191a. Thus, the conduction between the element-side bond portion 191 and the first electrode 21 is properly maintained.

The second terminal portion 192 is located on the second side in the first direction x (the left side in FIG. 33) with respect to the die pad 12 of the lead 1A. The second terminal portion 192 is exposed from the sealing resin 7 and extends toward the second side in the first direction x while bending in the middle. The second terminal portions 192 is an example of the terminal portion” that extends in a direction orthogonal to the thickness direction z (the first direction x in the illustrated example). The second terminal portion 192 has a reverse-surface mount portion 194. The reverse-surface mount portion 194 faces the second side in the thickness direction z (the lower side in FIG. 33). When the semiconductor device A20 is mounted on a circuit board, not shown, the reverse-surface mount portion 194 is bonded with a bonding material, such as solder. The second terminal portion 18 of a lead 1C and the second terminal portion 192 of a lead 1D are spaced apart from each other in the second direction y. The two second terminal portions 18 of the two leads 1C and the two second terminal portions 192 of the two leads 1D are alternately arranged at intervals in the second direction y.

The intermediate portion 193 is located between the element-side bond portion 191 and the second terminal portion 192 in the first direction x. The intermediate portion 193 is connected to the element-side bond portion 191 and the second terminal portion 192.

In the present embodiment, as shown in FIGS. 30, 31 and 35, each of the second terminal portions 18 and the second terminal portions 192 includes a first side wall 105 and a second side wall 115. In each of the second terminal portions 18 and the second terminal portions 192, the configurations of the first side wall 105 and the second side wall 115 differ from those of the first embodiment. In the present embodiment, the third side portion 108 and the sixth side portion 118 are provided at bent portions of the second terminal portions 18 and 192. Also, the first side portion 106 and the second side portion 107 are stepped toward the second side in the second direction y with respect to the third side portion 108. Likewise, the fourth side portion 116 and the fifth side portion 117 are stepped toward the first side in the second direction y with respect to the sixth side portion 118.

In the semiconductor device A20 of the present embodiment, each of the second terminal portions 18 and 192 has a first end surface 119 instead of the first end portion 104 of the semiconductor device A10 of the above-described embodiment. The first end surface 119 is located at the extremity in the direction in which the second terminal portions 18 and 192 extend (the first direction x), and faces the first side in the first direction x. The first end surface 119 is not covered with the metal layer 102. The first end surface 119 is a cut surface formed by cutting, for example, a metal plate (lead frame) used for manufacturing the semiconductor device, where the surface of the base material 101 is exposed.

According to the semiconductor device A20 of the present embodiment, in each first terminal portion 13, the first end portion 104, which is the extremity of the first terminal-extending portion 103, and the first side portion 106 of the first side wall 105 connected to the first end portion 104 are covered with a metal layer 102. Therefore, cutting the lead frame during the manufacture of the semiconductor device A20 does not generate metal burrs at these portions. This eliminates the likelihood that the metal burrs generated by cutting the lead frame protrude from the extremity of the first terminal portions 13. Therefore, a decrease in the reliability of mounting the semiconductor device A20 on a circuit board, for example, is suppressed.

The metal layer 102 covers the area around the extremity (the first end surface 104 and the first side portion 106) of the first terminal-extending portion 103. The metal layer 102 is a plating layer and has a higher solder wettability than that of the base material 101. Therefore, when the semiconductor device A20 is mounted on a circuit board with solder, the end surface and the side surface connected thereto of the first terminal portion 13 are covered with solder. This increases the mounting strength of the semiconductor device A20 and improves the mounting reliability of the semiconductor device A20. Additionally, the same effects as those of the above-described embodiment are provided due to the configuration in common with the semiconductor device A10 of the above-described embodiment.

A variation of the second embodiment:

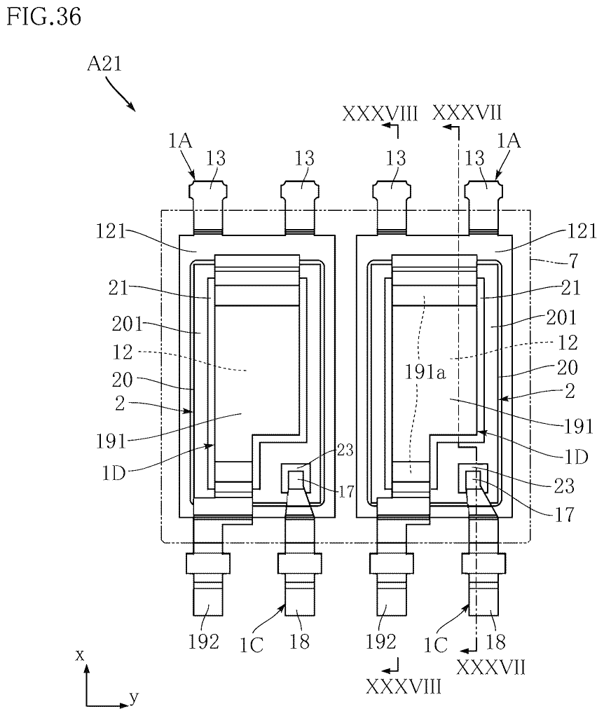

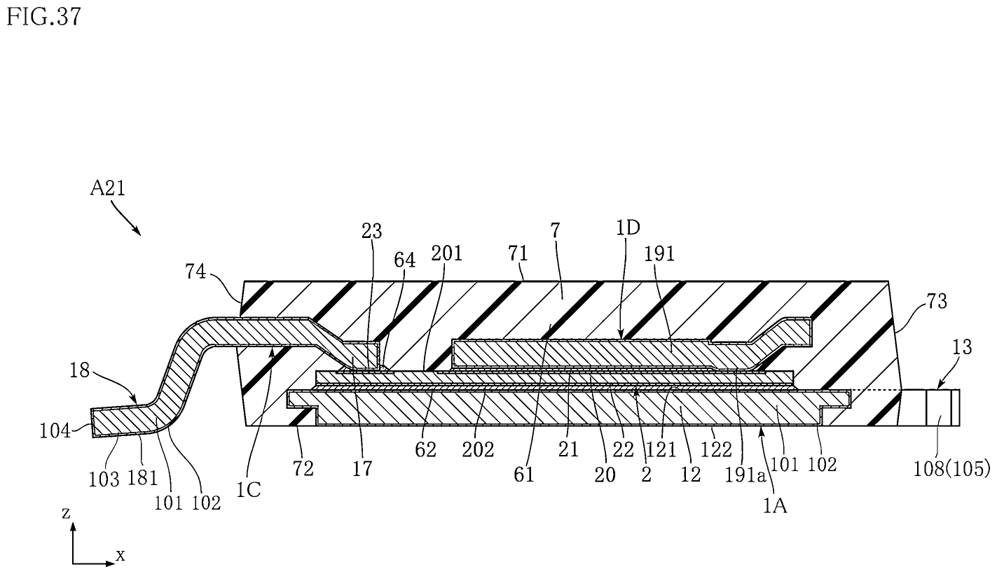

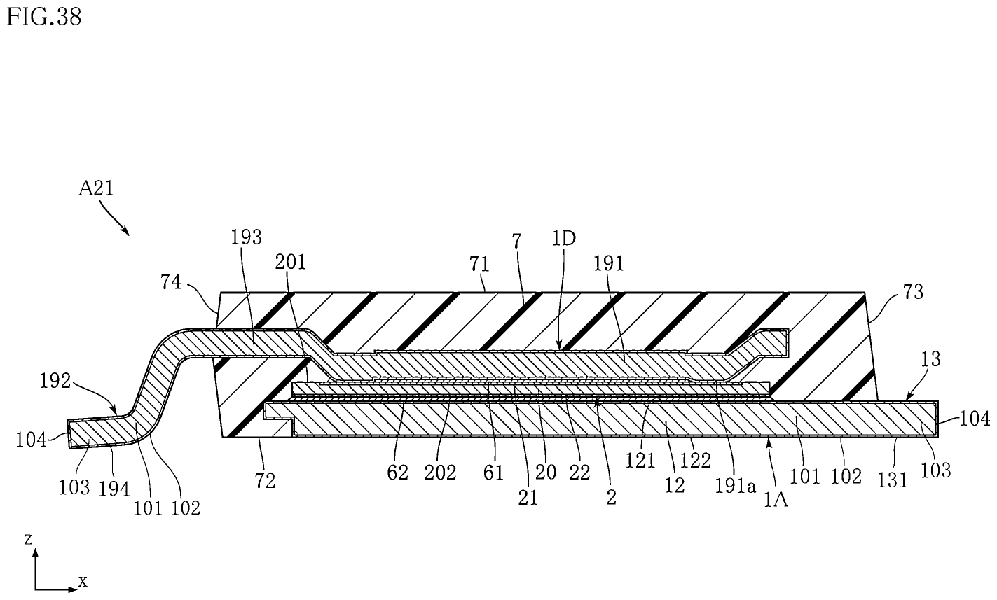

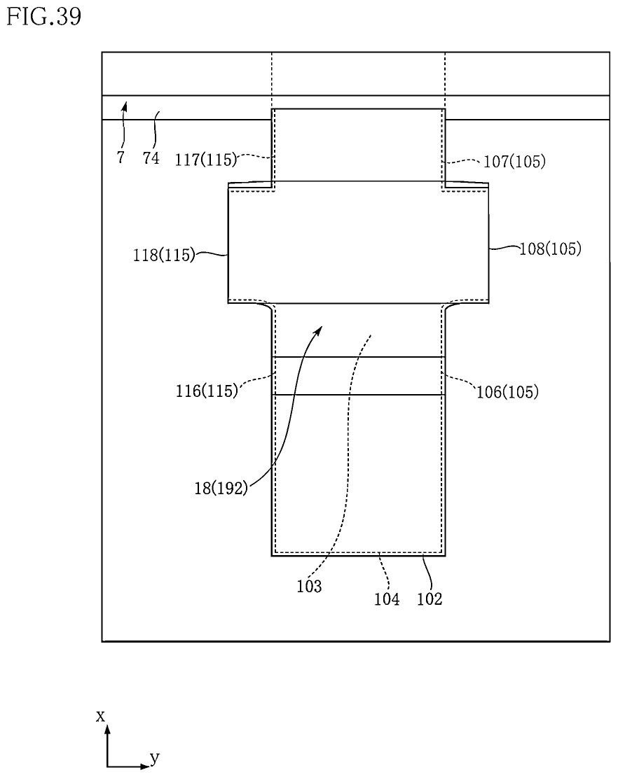

FIGS. 36 to 39 show a semiconductor device A21 according to a variation of the second embodiment. FIG. 36 is a plan view of the semiconductor device A21. FIG. 37 is a sectional view taken along line XXXVII-XXXVII in FIG. 36. FIG. 38 is a sectional view taken along line XXXVIII-XXXVIII in FIG. 36. FIG. 39 is a partial enlarged view of FIG. 36 (enlarged view of the area around a second terminal portion 18 or 192). In FIG. 36, the sealing resin 7 is transparent for the convenience of understanding.

As shown in FIGS. 37 to 39, in the semiconductor device A21 of the present variation, the base materials 101 forming the leads 1C and 1D have first terminal-extending portions 103. In the present variation, the base material 101 of each of the leads 1C and 1D has a first terminal-extending portion 103. The base material 101 of each lead 1C includes a first terminal-extending portion 103 correspondingly to the second terminal portion 18. In the base material 101 of the lead 1C, the first terminal-extending portion 103 is a portion forming the second terminal portion 18. The base material 101 of each lead 1D includes a first terminal-extending portion 103 correspondingly to the second terminal portion 192. In the base material 101 of the lead 1D, the first terminal-extending portion 103 is a portion forming the second terminal portion 192.

The first terminal-extending portion 103 of each of the second terminal portions 18 and 192 is exposed from the sealing resin 7 and extends in a direction orthogonal to the thickness direction z (the first direction x in the present embodiment) as a whole. Herein, the expression “the first terminal-extending portion 103 extends in the first direction x as a whole” means that the first terminal-extending portion 103 extends pointing in the first direction x as a whole, and includes the situation where the first terminal-extending portion 103 includes a bent portion as in the present variation. The first terminal-extending portion 103 of each of the second terminal portions 18 and 192 includes a first end portion 104, a first side wall 105, and a second side wall 115.

The first terminal-extending portion 103 of each of the second terminal portions 18 and 192 differs from the first embodiment in configuration of the first side wall 105 and the second side wall 115. In the present variation, the third side portion 108 and the sixth side portion 118 are provided at the bent portion of the first terminal-extending portion 103. Also, the first side portion 106 and the second side portion 107 are stepped toward the second side in the second direction y with respect to the third side portion 108. Likewise, the fourth side portion 116 and the fifth side portion 117 are stepped toward the first side in the second direction y with respect to the sixth side portion 118.

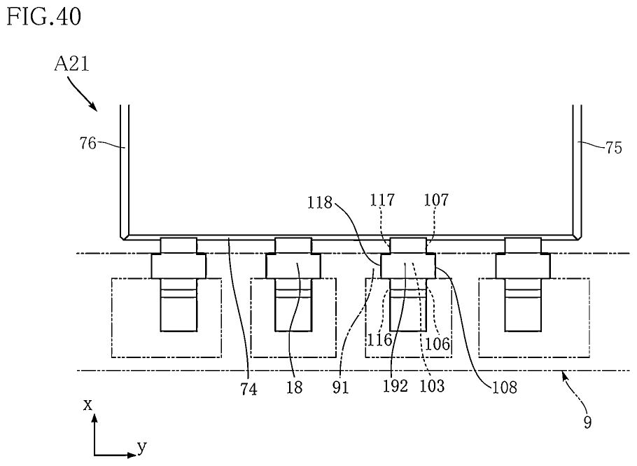

FIG. 40 is a plan view showing a part of the lead frame used in manufacturing the semiconductor device A21. In FIG. 40, the lead frame 9 before cutting is indicated by imaginary lines (dash-double dot lines). In the lead frame 9, the entire surface of the base material is covered with a metal layer. The lead frame 9 has a bar-shaped part 91 extending in the second direction y to intersect the second terminal portions 18 and 192 at their intermediate sections in the first direction x. The width of the bar-shaped part 91 in the first direction x is made relatively small. The bar-shaped part 91 of the lead frame 9 is cut along an xz-plane at locations near the first side portion 106 and the second side portion 107 and at locations near the fourth side portion 116 and the fifth side portion 117. As a result, a plurality of first terminal-extending portions 103, in which the third side portion 108 and the sixth side portion 118 are the cut surfaces (surfaces of the base material 101) , are formed.

According to the semiconductor device A21 of the present embodiment, in each of the first terminal portions 13 and the second terminal portions 18 and 192, the first end portion 104, which is the extremity of the first terminal-extending portion 103, and the first side portion 106 of the first side wall 105 connected to the first end portion 104 are covered with a metal layer 102. Therefore, cutting the lead frame 9 during the manufacture of the semiconductor device A21 does not generate metal burrs at these portions. This eliminates the likelihood that the metal burrs generated by cutting the lead frame 9 protrude from the extremity of the first terminal portions 13 and the second terminal portions 18 and 192. Therefore, a decrease in the reliability of mounting the semiconductor device A21 on a circuit board, for example, is suppressed.

The metal layer 102 covers the area around the extremity (the first end surface 104 and the first side portion 106) of the first terminal-extending portion 103. The metal layer 102 is a plating layer and has a higher solder wettability than that of the base material 101. Therefore, when the semiconductor device A21 is mounted on a circuit board with solder, the end surface and the side surface connected thereto of the first terminal portion 13 and the second terminal portions 18 and 192 are covered with solder. This increases the mounting strength of the semiconductor device A21 and improves the mounting reliability of the semiconductor device A21. Additionally, the same effects as those of the above-described embodiment are provided due to the configuration in common with the semiconductor device A10 of the above-described embodiment.

The semiconductor device according to the present disclosure is not limited to the above-described embodiments. Various modifications in design may be made freely in the specific structure of each part of the semiconductor device according to the present disclosure.

Although all of the terminal portions (the first terminal portions 13, the second terminal portions 15, and the second terminal portion 18) have the first terminal-extending portion 103 in the above-described first embodiment, the present disclosure is not limited to this. Only some of the terminal portions may have the first terminal-extending portion. For example, the terminal portions at four corners of the semiconductor device as viewed in the thickness direction may have the first terminal-extending portion.

Although the first end portion 104 of the first terminal-extending portion 103 is a flat surface in the above-described embodiments, the present disclosure is not limited to this. For example, the first end portion 104 may be a curved surface. The present disclosure includes embodiments described in the following clauses.

### Clause 1

A semiconductor device comprising:
a lead including a die pad and a plurality of terminal portions, the die pad including a first surface facing a first side in a thickness direction;
a semiconductor element mounted on the first surface; and
a sealing resin covering the semiconductor element, at least a part of the die pad, and a part of each of the plurality of terminal portions, wherein
the lead includes a base material and a metal layer covering a part of the base material,
the base material includes a first terminal-extending portion forming at least one of the plurality of terminal portions,
the first terminal-extending portion is exposed from the sealing resin, extends in a first direction orthogonal to the thickness direction, and includes a first end portion and a first side wall, the first end portion facing in the first direction, the first side wall facing in a second direction orthogonal to the thickness direction and the first direction,
the first side wall includes a first side portion located closer to the first end portion in the first direction, a second side portion located closer to the sealing resin in the first direction, and a third side portion located between the first side portion and the second side portion in the first direction, and
the metal layer covers the first end portion, the first side portion, and the second side portion, and is provided at a location avoiding the third side portion.

### Clause 2

The semiconductor device according to clause 1, wherein each of the plurality of terminal portions extends in the first direction.

### Clause 3

The semiconductor device according to clause 2, wherein the plurality of terminal portions include a plurality of first terminal portions, and
the plurality of first terminal portions are located on a first side in the first direction with respect to the die pad to extend toward the first side in the first direction and arranged at intervals in the second direction.

### Clause 4

The semiconductor device according to clause 3, wherein each of the plurality of first terminal portions is connected to the die pad on the first side in the first direction.

### Clause 5

The semiconductor device according to clause 4, wherein the plurality of terminal portions include a plurality of second terminal portions, and
the plurality of second terminal portions are located on a second side in the first direction with respect to the die pad to extend toward the second side in the first direction and arranged at intervals in the second direction.

### Clause 6

The semiconductor device according to clause 5, wherein, of the plurality of first terminal portions, those located at one end and at another end in the second direction each include the first terminal-extending portion, and of the plurality of second terminal portions, those located at one end and at another end in the second direction each include the first terminal-extending portion.

### Clause 7

The semiconductor device according to any one of clauses 1 to 6, wherein the third side portion is a flat surface facing the first side in the second direction.

### Clause 8

The semiconductor device according to clause 7, wherein the first side portion and the second side portion are located on a second side in the second direction with respect to the third side portion.

### Clause 9

The semiconductor device according to clause 8, wherein the first side portion extends toward the second side in the second direction as proceeding away from the third side portion in the first direction.

### Clause 10

The semiconductor device according to clause 8 or 9, wherein the second side portion includes a second-side first part and a second-side second part, the second-side first part being a flat surface facing the first side in the second direction, the second-side second part being connected to the second-side first part and the third side portion and extending toward the second side in the second direction as proceeding away from the third side portion in the first direction.

### Clause 11

The semiconductor device according to any one of clauses 1 to 10, wherein a first dimension of the first side portion in the first direction is smaller than a second dimension of the second side portion in the first direction.

### Clause 12

The semiconductor device according to any one of clauses 1 to 11, wherein a ratio of a length of the third side portion in the first direction to a length of the first side wall in the first direction is in a range of 0.25 to 0.7 times.

### Clause 13

The semiconductor device according to any one of clauses 1 to 12, wherein the first terminal-extending portion includes a second side wall facing a side opposite to a side that the first side wall faces in the second direction,
the second side wall includes a fourth side portion located closer to the first end portion in the first direction, a fifth side portion located closer to the sealing resin in the first direction, and a sixth side portion located between the fourth side portion and the fifth side portion in the first direction, and
the metal layer covers the fourth side portion and the fifth side portion and is provided at a location avoiding the sixth side portion.

### Clause 14

The semiconductor device according to clause 13, wherein the sixth side portion is a flat surface facing the second side in the second direction.

### Clause 15

The semiconductor device according to clause 14, wherein the fourth side portion and the fifth side portion are located on the first side in the second direction with respect to the sixth side portion.

### Clause 16

The semiconductor device according to clause 15, wherein the fourth side portion extends toward the first side in the second direction as proceeding away from the sixth side portion in the first direction.

### Clause 17

The semiconductor device according to clause 15 or 16, wherein the fifth side portion includes a fifth-side first part and a fifth-side second part, the fifth-side first part being a flat surface facing the second side in the second direction, the fifth-side second part being connected to the fifth-side first part and the sixth side portion and extending toward the first side in the second direction as proceeding away from the sixth side portion in the first direction.

### Clause 18

The semiconductor device according to any one of clauses 13 to 17, wherein a third dimension of the fourth side portion in the first direction is smaller than a fourth dimension of the fifth side portion in the first direction.

### Clause 19

The semiconductor device according to any one of clauses 13 to 18, wherein a ratio of a length of the sixth side portion in the first direction to a length of the second side wall in the first direction is in a range of 0.25 to 0.7 times.

### Clause 20

The semiconductor device according to any one of clauses 1 to 19, wherein the first end portion is a flat surface facing in the first direction.

### Clause 21

The semiconductor device according to any one of clauses 1 to 20, wherein the metal layer is a plating layer.

### REFERENCE NUMERALS

A10, A11, A12, A20, A21: Semiconductor device
1A, 1B, 1C, 1D: Lead 101: Base material
102: Metal layer 103: First terminal-extending portion
104: First end portion 105: First side wall
106: First side portion 107: Second side portion
107a: Second-side first part 107b: Second-side second part
108: Third side portion 115: Second side wall
116: Fourth side portion 117: Fifth side portion
117a: Fifth-side first part 117b: Fifth-side second part
118: Sixth side portion 119: First end surface
12: Die pad 121: First surface
122: Reverse-surface mount portion
13: First terminal portion
131: Reverse-surface mount portion 132: End surface
14: Pad portion 15: Second terminal portion
151: Reverse-surface mount portion 16: Bent portion
17: Pad portion 18: Second terminal portion
181: Reverse-surface mount portion 19: Bent portion
191: Element-side bond portion 191a: Protrusion
192: Second terminal portion 193: Intermediate portion
194: Reverse-surface mount portion 2: Semiconductor element
20: Element body 201: Element obverse surface
202: Element reverse surface 21: First electrode
212: First-electrode pad portion 22: Second electrode
23: Third electrode 3: Insulating part
4: Metal laminate part 5: Conductive member
51: Element-side bond portion 511: Protrusion
512: Recess 52: Lead-side bond portion
53: Intermediate portion
61, 62, 63, 64: Conductive bonding material
65: Wire 7: Sealing resin
71: Resin obverse surface 72: Resin reverse surface
73, 74, 75, 76: Resin side surface 9: Lead frame
91: Bar-shaped part 911, 912, 913, 914: Recess
L1: First dimension L2: Second dimension
L3: Third dimension L4: Fourth dimension
x: First direction y: Second direction
z: Thickness direction

1. A semiconductor device comprising:
a lead including a die pad and a plurality of terminal portions, the die pad including a first surface facing a first side in a thickness direction;
a semiconductor element mounted on the first surface; and
a sealing resin covering the semiconductor element, at least a part of the die pad, and a part of each of the plurality of terminal portions, wherein
the lead includes a base material and a metal layer covering a part of the base material,
the base material includes a first terminal-extending portion forming at least one of the plurality of terminal portions,
the first terminal-extending portion is exposed from the sealing resin, extends in a first direction orthogonal to the thickness direction, and includes a first end portion and a first side wall, the first end portion facing in the first direction, the first side wall facing in a second direction orthogonal to the thickness direction and the first direction,
the first side wall includes a first side portion located closer to the first end portion in the first direction, a second side portion located closer to the sealing resin in the first direction, and a third side portion located between the first side portion and the second side portion in the first direction, and
the metal layer covers the first end portion, the first side portion, and the second side portion, and is provided at a location avoiding the third side portion.

2. The semiconductor device according to claim 1, wherein each of the plurality of terminal portions extends in the first direction.

3. The semiconductor device according to claim 2, wherein the plurality of terminal portions include a plurality of first terminal portions, and
the plurality of first terminal portions are located on a first side in the first direction with respect to the die pad to extend toward the first side in the first direction and arranged at intervals in the second direction.

4. The semiconductor device according to claim 3, wherein each of the plurality of first terminal portions is connected to the die pad on the first side in the first direction.

5. The semiconductor device according to claim 4, wherein the plurality of terminal portions include a plurality of second terminal portions, and
the plurality of second terminal portions are located on a second side in the first direction with respect to the die pad to extend toward the second side in the first direction and arranged at intervals in the second direction.

6. The semiconductor device according to claim 5, wherein, of the plurality of first terminal portions, those located at one end and at another end in the second direction each include the first terminal-extending portion, and of the plurality of second terminal portions, those located at one end and at another end in the second direction each include the first terminal-extending portion.

7. The semiconductor device according to claim 1, wherein the third side portion is a flat surface facing the first side in the second direction.

8. The semiconductor device according to claim 7, wherein the first side portion and the second side portion are located on a second side in the second direction with respect to the third side portion.

9. The semiconductor device according to claim 8, wherein the first side portion extends toward the second side in the second direction as proceeding away from the third side portion in the first direction.

10. The semiconductor device according to claim 8, wherein the second side portion includes a second-side first part and a second-side second part, the second-side first part being a flat surface facing the first side in the second direction, the second-side second part being connected to the second-side first part and the third side portion and extending toward the second side in the second direction as proceeding away from the third side portion in the first direction.

11. The semiconductor device according to claim 1, wherein a first dimension of the first side portion in the first direction is smaller than a second dimension of the second side portion in the first direction.

12. The semiconductor device according to claim 1, wherein a ratio of a length of the third side portion in the first direction to a length of the first side wall in the first direction is in a range of 0.25 to 0.7 times.

13. The semiconductor device according to claim 1, wherein the first terminal-extending portion includes a second side wall facing a side opposite to a side that the first side wall faces in the second direction,
the second side wall includes a fourth side portion located closer to the first end portion in the first direction, a fifth side portion located closer to the sealing resin in the first direction, and a sixth side portion located between the fourth side portion and the fifth side portion in the first direction, and
the metal layer covers the fourth side portion and the fifth side portion and is provided at a location avoiding the sixth side portion.

14. The semiconductor device according to claim 13, wherein the sixth side portion is a flat surface facing the second side in the second direction.

15. The semiconductor device according to claim 14, wherein the fourth side portion and the fifth side portion are located on the first side in the second direction with respect to the sixth side portion.

16. The semiconductor device according to claim 15, wherein the fourth side portion extends toward the first side in the second direction as proceeding away from the sixth side portion in the first direction.

17. The semiconductor device according to claim 15, wherein the fifth side portion includes a fifth-side first part and a fifth-side second part, the fifth-side first part being a flat surface facing the second side in the second direction, the fifth-side second part being connected to the fifth-side first part and the sixth side portion and extending toward the first side in the second direction as proceeding away from the sixth side portion in the first direction.

18. The semiconductor device according to claim 13, wherein a third dimension of the fourth side portion in the first direction is smaller than a fourth dimension of the fifth side portion in the first direction.

19. The semiconductor device according to claim 13, wherein a ratio of a length of the sixth side portion in the first direction to a length of the second side wall in the first direction is in a range of 0.25 to 0.7 times.

20. The semiconductor device according to claim 1, wherein the first end portion is a flat surface facing in the first direction.

21. The semiconductor device according to claim 1, wherein the metal layer is a plating layer.
